(19) United States
(12) Patent Application Publication
(10) Pub. No.: US 2023/0365902 A1
(43) Pub. Date: Nov. 16, 2023

(54) COMPOSITION AND SUBSTRATE WASHING METHOD

(71) Applicant: FUJIFILM Corporation, Tokyo (JP)

(72) Inventor: Atsushi MIZUTANI, Shizuoka (JP)

(73) Assignee: FUJIFILM Corporation, Tokyo (JP)

(21) Appl. No.: 18/357,360

(22) Filed: Jul. 24, 2023

Related U.S. Application Data
(63) Continuation of application No. PCT/JP22/00716, filed on Jan. 12, 2022.

(30) Foreign Application Priority Data
Jan. 29, 2021 (JP) 2021-013634
Dec. 14, 2021 (JP) 2021-202586

(51) Int. Cl. C11D 11/00; C11D 7/50; C11D 7/26; C11D 7/32; C11D 7/34; C11D 7/36

(52) U.S. Cl. CPC C11D 11/0047; C11D 7/5009; C11D 7/261; C11D 7/3281; C11D 7/3218; C11D 7/34; C11D 7/265; C11D 7/3245; C11D 7/36; H01L 21/02068

(57) ABSTRACT

The present invention provides a composition for a semiconductor device, which is excellent in residue removability. In addition, the present invention provides a substrate washing method using the treatment liquid. The composition for a semiconductor device contains alcohol, an aprotic polar solvent, an azole compound, an alkanolamine, and water.

### CROSS-REFERENCE TO RELATED APPLICATIONS

This application is a Continuation of PCT International Application No. PCT/JP2022/000716 filed on Jan. 12, 2022, which claims priority under 35 U.S.C. § 119(a) to Japanese Patent Application No. 2021-013634 filed on Jan. 29, 2021 and Japanese Patent Application No. 2021-202586 filed on Dec. 14, 2021. The above applications are hereby expressly incorporated by reference, in their entirety, into the present application.

### BACKGROUND OF THE INVENTION

### 1. Field of the Invention

The present invention relates to a composition and a substrate washing method.

### 2. Description of the Related Art

Semiconductor devices such as charge-coupled devices (CCD) and memories are manufactured by forming fine electronic circuit patterns on a substrate, using photolithography technology. The semiconductor devices are manufactured, for example, by disposing a laminate having a metal layer serving as a wiring line material, an etching stop film, and an interlayer insulating film on a substrate, forming a resist film on this laminate, and carrying out a photolithography step and a dry etching step (for example, a plasma etching treatment).

Specifically, in the photolithography step, the metal layer and/or the interlayer insulating film on the substrate is etched by a dry etching treatment using the obtained resist film as a mask.

In this case, residues derived from the metal layer and/or the interlayer insulating film and the like may adhere to the substrate, the metal layer, and/or the interlayer insulating film. In order to remove the adhered residues, washing using a treatment liquid is often carried out.

In addition, the resist film used as a mask during etching is then removed from the laminate by a dry-type method (dry ashing) by ashing (incineration), a wet-type method, or the like. The residues derived from the resist film or the like may adhere to the laminate from which the resist has been removed by using the dry ashing method. In order to remove the adhered residues, washing using a treatment liquid is often carried out. On the other hand, examples of the aspect of the wet-type method for removing the resist film include an aspect of removing the resist film using a treatment liquid.

As described above, the treatment liquid is used for removing residues (etching residues and ashing residues) and/or a resist film in the semiconductor device manufacturing step.

For example, WO2009/051237A discloses a stripper composition containing a combination of alkanolamines, aromatic alcohols, and an anticorrosive agent.

### SUMMARY OF THE INVENTION

As a result of studying the composition described in WO2009/051237A, the inventors of the present invention revealed that there is room for further improvement in the residue removability (particularly, the residue removability after dry etching) of the composition.

Therefore, an object of the present invention is to provide a composition for a semiconductor device, which is excellent in residue removability (particularly, residue removability after dry etching).

In addition, an object of the present invention is to provide a substrate washing method using the treatment liquid.

As a result of diligent studies to achieve the objects, the inventors of the present invention found that the objects can be achieved by the following configurations.

[1] A composition for a semiconductor device, comprising:
alcohol;
an aprotic polar solvent;
an azole compound;
an alkanolamine; and
water.

[2] The composition according to [1], in which a pH is 9 to 11.

[3] The composition according to [1] or [2], in which the alcohol includes a monoalcohol.

[4] The composition according to [1] or [2], in which the alcohol includes a monoalcohol having a main chain skeleton consisting of an aliphatic hydrocarbon group and an alcoholic hydroxyl group, or a polyhydric alcohol having a main chain skeleton consisting of an aliphatic hydrocarbon group and an alcoholic hydroxyl group.

[5] The composition according to any one of [1] to [4], in which the aprotic polar solvent includes at least one selected from the group consisting of dimethyl sulfoxide or sulfolane.

[6] The composition according to any one of [1] to [5], in which the aprotic polar solvent includes sulfolane.

[7] The composition according to any one of [1] to [6], further comprising a component A selected from the group consisting of sulfolene and dipropyl sulfone.

[8] The composition according to [7], in which a content of the component A is 100 ppt by mass or more and 100 ppm by mass or less with respect to a total mass of the composition.

[9] The composition according to [7] or [8], in which a mass ratio of a content of the azole compound to a content of the component A is 1.0×10³ to 1.0×10¹⁰.

[10] The composition according to any one of [7] to [9], in which a mass ratio of the content of the aprotic polar solvent to a content of the component A is 1.0×10⁴ to 1.0×10¹⁰.

[11] The composition according to any one of [1] to [10], in which the alcohol includes at least one selected from the group consisting of methanol, ethanol, 1-propanol, 2-propanol, 1-butanol, 2-butanol, t-butanol, 1-pentanol, 3-pentanol, and cyclopentanol.

[12] The composition according to any one of [1] to [11], in which a content of the alcohol is 50% to 80% by mass with respect to a total mass of the composition.

[13] The composition according to any one of [1] to [12], in which a content of the aprotic polar solvent is 1% to 20% by mass with respect to a total mass of the composition.

[14] The composition according to any one of [1] to [13], in which the azole compound includes at least one selected from the group consisting of 1,2,4-triazole, 1,2,3-triazole, 1H-tetrazole, 5-aminotetrazole, 1H-benzotriazole, tolyltriazole, 5-methyltriazole, carboxybenzotriazole, and 2,2′-[{(methyl-1H-benzotriazole-1-yl)methyl}imino]bisethanol.

[15] The composition according to any one of [1] to [14], in which a content of the azole compound is 0.1% to 5% by mass with respect to a total mass of the composition.

[16] The composition according to any one of [1] to [15], in which a content of the water is 10% to 40% by mass with respect to a total mass of the composition.

[17] The composition according to any one of [1] to [16], in which the alkanolamine includes at least one selected from the group consisting of diethanolamine, 2-(2-aminoethylamino)ethanol, 2-(2-aminoethoxy)ethanol, triethanolamine, 2-aminoethanol, N,N-dimethylethanolamine, N,N-diethylethanolamine, N-methyldiethanolamine, N-ethyldiethanolamine, and N-methylethanolamine.

[18] The composition according to any one of [1] to [17], in which a content of the alkanolamine is 0.3% to 10% by mass with respect to a total mass of the composition.

[19] The composition according to any one of [1] to [18], further comprising a chelating agent.

[20] The composition according to [19], in which the chelating agent has two or more coordinating groups selected from the group consisting of a carboxy group, a phosphonate group, a phosphate group, and an amino group.

[21] The composition according to [19] or [20], in which the chelating agent includes at least one selected from the group consisting of an amino polycarboxylic acid and a polycarboxylic acid.

[22] A substrate washing method comprising a washing step of washing a substrate including a metal layer, by using the composition according to any one of [1] to [21].

According to the present invention, it is possible to provide a composition for a semiconductor device, which is excellent in residue removability (particularly, residue removability after dry etching).

In addition, according to the present invention, it is possible to provide a substrate washing method using the treatment liquid.

### BRIEF DESCRIPTION OF THE DRAWINGS

FIG. 1 is a schematic cross-sectional view illustrating an example of a laminate which is an object to be washed in a substrate washing method.

### DESCRIPTION OF THE PREFERRED EMBODIMENTS

Hereinafter, the present invention will be described in detail.

Descriptions of the configuration requirements which will be described later are made based on representative embodiments of the present invention in some cases, but it should not be construed that the present invention is limited to such embodiments.

In the present specification, the numerical value range indicated by using “to” means a range including the numerical values before and after “to” as the lower limit value and the upper limit value, respectively.

In the present specification, the “preparation” is meant to include supplying a predetermined material by purchases or the like, in addition to providing specific materials by synthesis, combination, or the like.

In the present specification, in a case where two or more kinds of a certain component are present, the “content” of the component means a total content of the two or more kinds of the component.

In the present specification, “ppm” means “parts-per-million (10⁻⁶)”, “ppb” means “parts-per-billion (10⁻⁹)”, and “ppt” means “parts-per-trillion (10⁻¹²)”.

In the present specification, 1 Å (angstrom) corresponds to 0.1 nm.

In addition, the present specification, in a case where there is no description regarding whether a group (atomic group) is substituted or unsubstituted, as long as the effect of the present specification is not reduced, the group includes both the group having no substituent and the group having a substituent. For example, the “hydrocarbon group” refers to not only a hydrocarbon group not having a substituent (unsubstituted hydrocarbon group) but also a hydrocarbon group having a substituent (substituted hydrocarbon group). This also applies to each compound.

In the present specification, light means actinic rays or radiation. In the present specification, the “radiation” means, for example, a bright line spectrum of a mercury lamp, far ultraviolet rays typified by an excimer laser, extreme ultraviolet rays (EUV rays), X-rays, or electron beams. Unless otherwise specified, the “exposure” in the present specification includes not only exposure with a bright line spectrum of a mercury lamp, far ultraviolet rays represented by an excimer laser, X-rays, or EUV rays, but also the exposure includes drawing with particle beams such as electron beams and ion beams.

[Composition]

The composition according to the embodiment of the present invention (hereinafter, also referred to as “the present composition”) is a composition for a semiconductor device, containing at least alcohol, an aprotic polar solvent, an azole compound, an alkanolamine, and water.

The inventors of the present invention found that in a case where the composition contains a combination of the above-described components, the residue removability (particularly, the residue removability after dry etching) is excellent (hereinafter, also referred to as “the effect of the present invention is excellent”), whereby the present invention was completed.

Hereinafter, each component contained in the present composition will be described.

[Alcohol]

The alcohol contained in the present composition is a compound having at least one alcoholic hydroxyl group.

It is noted that in this specification, the alkanolamine and the azole compound, which will be described later, are not included in the alcohol.

Examples of the alcohol include a compound having a main chain skeleton including a chain-like or cyclic aliphatic hydrocarbon group and having at least one alcoholic hydroxyl group. It is noted that in the main chain skeleton, one or more methanediyl groups (—CH₂—) constituting a chain-like or cyclic aliphatic hydrocarbon group may be substituted with a heteroatom. Examples of the heteroatom include —O— and —S—. In addition, the alcoholic hydroxyl group is bonded to the main chain skeleton.

The alcohol may be a monoalcohol having one alcoholic hydroxyl group or may be a polyhydric alcohol having two or more alcoholic hydroxyl groups.

The alcohol is preferably a monoalcohol or a polyhydric alcohol having two or three alcoholic hydroxyl groups, more preferably a monoalcohol or a polyhydric alcohol having two alcoholic hydroxyl groups, and still more preferably a monoalcohol.

From the viewpoint that the effect of the present invention is more excellent, the alcohol is preferably a compound having a main chain skeleton consisting of an aliphatic hydrocarbon group which does not have a heteroatomic atom such as an ether group (—O—), and having an alcoholic hydroxyl group bonded to the main chain skeleton (a monoalcohol or a polyhydric alcohol).

In addition, the main chain skeleton of the alcohol is preferably a chain-like main chain skeleton that does not have a cyclic structure from the viewpoint that anticorrosion properties (Co anticorrosion properties) with respect to a metal layer containing Co are more excellent.

That is, the alcohol is preferably a compound having a main chain skeleton and an alcoholic hydroxyl group bonded to the main chain skeleton, where the main chain skeleton is a main chain skeleton consisting of an aliphatic hydrocarbon group and/or a chain-like main chain skeleton, among which a compound having a main chain skeleton consisting of a chain-like aliphatic hydrocarbon group having no heteroatom and having an alcoholic hydroxyl group is more preferable.

The number of carbon atoms of the aliphatic hydrocarbon group constituting the main chain skeleton is not particularly limited; however, it is preferably 1 to 8 and more preferably 2 to 6.

Examples of the monoalcohol having a main chain skeleton consisting of a chain-like aliphatic hydrocarbon group include methanol, ethanol, 1-propanol, 2-propanol (isopropanol), 1-butanol, 2-butanol, isobutyl alcohol, and tert-butyl alcohol, 2-pentanol, t-pentyl alcohol, 1-hexanol, allyl alcohol, propargyl alcohol, 2-butenyl alcohol, 3-butenyl alcohol, and 4-pentene-2-ol.

Examples of the polyhydric alcohol having a main chain skeleton consisting of a chain-like aliphatic hydrocarbon group include ethylene glycol, propylene glycol, 2-methyl-1,3-propanediol, 1,3-propanediol, 2,2-dimethyl-1,3-propanediol, 1,4-butanediol, 1,3-butanediol, 1,2-butanediol, 2,3-butanediol, and pinacol.

Examples of the alcohol having a main chain skeleton consisting of an aliphatic hydrocarbon group and having a cyclic structure include cyclopentanol, cyclohexanol, and 1,3-cyclopentanediol.

Examples of the alcohol having a main chain structure obtained by substituting one or more carbon atoms constituting a chain-like aliphatic hydrocarbon group with an ether group (—O—) include a mono or poly(alkyleneoxy)alkyl ether, and more specific examples thereof include an ethylene glycol monoalkyl ether, diethylene glycol, a diethylene glycol monoalkyl ether, triethylene glycol, a triethylene glycol monoalkyl ether, tetraethylene glycol, hexylene glycol, 1-methoxy-2-propanol, 2-methoxy-1-propanol, 1-ethoxy-2-propanol, 2-ethoxy-1-propanol, propylene glycol mono-n-propyl ether, a dipropylene glycol monoalkyl ether, a tripropylene glycol monoalkyl ether, ethylene glycol monobenzyl ether, and diethylene glycol monobenzyl ether.

Examples of the alcohol having a cyclic structure and having a main chain structure obtained by substituting one or more carbon atoms constituting an aliphatic hydrocarbon group with an ether group (—O—) include tetrahydrofurfuryl alcohol.

The alcohol is preferably methanol, ethanol, 1-propanol, 2-propanol, 1-butanol, 2-butanol, t-butanol, 1-pentanol, 3-pentanol or cyclopentanol, more preferably ethanol, 1-propanol, 2-propanol, 1-butanol, 2-butanol, t-butanol, 1-pentanol, 3-pentanol, or cyclopentanol, and still more preferably 1-butanol, 2-butanol, or t-butanol.

In addition, the alcohol is preferably a hydrophilic alcohol. In the present specification, the hydrophilicity is intended to indicate that an amount of 0.1 g or more is dissolved in 100 g of water under a condition of 25° C. Among the above, an alcohol having a solubility of 10 g or more in 100 g of water under a condition of 25° C. or an alcohol that can be uniformly mixed with water at any mixing ratio is preferable.

One kind of the alcohol may be used alone, or two or more kinds thereof may be used in combination. Examples of the alcohol in a case where two or more kinds of alcohols are used in combination include the combination of alcohols described above.

The content of the alcohol is not particularly limited. However, from the viewpoint of more excellent washability, it is preferably 40% to 90% by mass, more preferably 50% to 80% by mass, and still more preferably 55% to 75% by mass, with respect to the total mass of the composition.

[Aprotic Polar Solvent]

The present composition contains an aprotic polar solvent.

In the present specification, the aprotic polar solvent means a compound which does not have a proton (hydrogen ion) donating property and has an electrical bias in the molecule.

Examples of the aprotic polar solvent include a sulfur-containing solvent and a ketone-based solvent.

Examples of the sulfur-containing solvent include dimethyl sulfone, dimethyl sulfoxide, and sulfolane.

Examples of the ketone-based solvent include acetone, methyl ethyl ketone, methyl isobutyl ketone, and cyclohexanone.

The aprotic polar solvent is preferably a sulfur-containing solvent, more preferably dimethyl sulfoxide or sulfolane, and still more preferably sulfolane.

One kind of the aprotic polar solvent may be used alone, or two or more kinds thereof may be used in combination.

From the viewpoint of more excellent residue removability, the content of the aprotic polar solvent is preferably 0.1% to 40% by mass, more preferably 1% to 20% by mass, and still more preferably 5% to 15%, with respect to the total mass of the composition.

[Azole Compound]

The azole compound is an aromatic compound having a hetero 5-membered ring that contains at least one nitrogen atom.

The number of nitrogen atoms contained in the hetero 5-membered ring of the azole compound is not particularly limited and is preferably 1 to 4, and more preferably 2 to 4.

The azole compound may have a substituent on the hetero 5-membered ring.

Examples of such a substituent include a hydroxy group, a carboxy group, a mercapto group, an amino group, and a substituted or unsubstituted hydrocarbon group. In addition, in a case where two substituents are adjacent to each other on the hetero 5-membered ring, the two substituents may be bonded to each other to form a ring.

Examples of the hydrocarbon group contained as a substituent in the hetero 5-membered ring include an alkyl group (preferably having 1 to 12 carbon atoms and more preferably 1 to 6 carbon atoms), an alkenyl group (preferably having 2 to 12 carbon atoms and more preferably 2 to 6 carbon atoms), an alkynyl group (preferably having 2 to 12 carbon atoms and more preferably 2 to 6 carbon atoms), an aryl group (preferably having 6 to 18 carbon atoms and more preferably 6 to 10), and an aralkyl group (preferably having 7 to 23 carbon atoms and more preferably 7 to 11 carbon atoms).

Examples of the substituent contained in the above-described hydrocarbon group include a hydroxy group, a carboxy group, and —N(Rₐ)(R_{b}). Rₐ and R_{b} each independently represent a hydrogen atom, an alkyl group (preferably having 1 to 6 carbon atoms and more preferably having 1 to 4 carbon atoms), or a hydroxyalkyl group (preferably having 1 to 6 carbon atoms and more preferably having 1 to 4 carbon atoms).

The ring that is formed by bonding two adjacent substituents on the hetero 5-membered ring to each other is not particularly limited; however, it is preferably an aromatic ring (may be either a monocyclic ring or a polycyclic ring) and more preferably a benzene ring. The above-described ring that is formed by bonding two substituents to each other may have a substituent. The substituent is not particularly limited. However, examples thereof include those exemplified as the substituent of the hydrocarbon group contained in the hetero 5-membered ring.

Examples of the azole compound include an imidazole compound in which one of the atoms constituting the azole ring is a nitrogen atom, a pyrazole compound in which two of the atoms constituting an azole ring are nitrogen atoms, a thiazole compound in which one of the atoms constituting an azole ring is a nitrogen atom and the other one is a sulfur atom, a triazole compound in which three of the atoms constituting an azole ring are nitrogen atoms, and a tetrazole compound in which four of the atoms constituting an azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazole carboxylic acid, histamine, and benzoimidazole.

Examples of the pyrazole compound include pyrazole, 4-pyrazolecarboxylic acid, 1-methylpyrazole, 3-methylpyrazole, 3-amino-5-hydroxypyrazole, 3-aminopyrazole, and 4-aminopyrazole.

Examples of the thiazole compound include 2,4-dimethylthiazole, benzothiazole, and 2-mercaptobenzothiazole.

Examples of the triazole compound include a compound having a benzotriazole skeleton obtained by bonding two adjacent substituents on a triazole ring to each other to form a benzene ring.

Examples of the compound having a benzotriazole skeleton include 1H-benzotriazole, 2H-benzotriazole, and a compound obtained by substituting a benzene ring of 1H-benzotriazole or 2H-benzotriazole, and/or a triazole ring, with at least one substituent selected from the group consisting of an alkyl group (preferably having 1 to 8 carbon atoms), an amino group, a hydroxy group, a carboxy group, a halogen atom, an aryl group, and a group consisting of a combination these groups.

More specific examples thereof include 1H-benzotriazole, 2H-benzotriazole, 5-methyl-1H-benzotriazole (CAS registration number: 136-85-6), tolyltriazole (CAS registration number: 29385-43-1), 5-aminobenzotriazole, 1-hydroxybenzotriazole, carboxybenzotriazole (for example, benzotriazole-5-carboxylic acid and 4-carboxybenzotriazole), 5,6-dimethylbenzotriazole, 1-[N,N-bis(hydroxyethyl)aminoethyl]benzotriazole, 1-(1,2-dicarboxyethyl)benzotriazole, 1-[N,N-bis(2-ethylhexyl)aminomethyl]benzotriazole, 1-[N,N-bis(2-ethylhexyl)aminomethyl]methylbenzotriazole, and 2,2′-{[(methyl-1H-benzotriazole-1-yl)methyl]imino}bisethanol.

Examples of the triazole compound other than the compound having a benzotriazole skeleton include 1,2,4-triazole, 3-methyl-1,2,4-triazole, 3-amino-1,2,4-triazole, 1,2,3-triazole, and 1-methyl-1,2,3-triazole.

Examples of the tetrazole compound include 1H-tetrazole (1,2,3,4-tetrazole), 5-methyl-1H-tetrazole, 5-amino-1H-tetrazole, 1,5-pentamethylenetetrazole, 1-phenyl-5-mercaptotetrazole, and 1-(2-dimethylaminoethyl)-5-mercaptotetrazole.

The azole compound is preferably a triazole compound or a tetrazole compound, more preferably at least one selected from the group consisting of 1,2,4-triazole, 1,2,3-triazole, 1H-tetrazole, 5-aminotetrazole, 1H-benzotriazole, tolyltriazole, 5-methyltriazole, carboxybenzotriazole, and 2, 2′-[{(methyl-1H-benzotriazole-1-yl)methyl}imino]bisethanol, and still more preferably 1,2,4-triazole, 1H-benzotriazole, tolyltriazole, 5-methyltriazole, or 2,2′-[{(methyl-1H-benzotriazole-1-yl)methyl}imino]bisethanol.

It is noted that in the present specification, the above-described azole compound is intended to include a tautomer thereof.

One kind of the azole compound may be used alone, or two or more kinds thereof may be used in combination.

From the viewpoint that the anticorrosion properties with respect to the metal layer such as the cobalt-containing layer and the tungsten-containing layer, the content of the azole compound is preferably 0.01% to 10% by mass, more preferably 0.1% to 6% by mass, still more preferably 0.1% to 5%, and even still more preferably 0.2% to 3% by mass, with respect to the total mass of the composition.

[Alkanolamine]

The present composition contains an alkanolamine.

The alkanolamine is an amine compound having at least one amino group in the molecule, where it is a compound further having at least one hydroxy group (preferably a hydroxylalkyl group).

Examples of the alkanolamine include a compound having a main chain skeleton consisting of a chain-like aliphatic hydrocarbon group, at least one amino group bonded to the main chain skeleton, and at least one alcoholic hydroxyl group bonded to the main chain skeleton. It is noted that in the main chain skeleton, one or more methanediyl groups (—CH₂—) constituting a chain-like aliphatic hydrocarbon group may be substituted with a heteroatom. Examples of the heteroatom include —O—, —S—, and —NH—, where —O— or —NH— is preferable.

The number of amino groups contained in the alkanolamine is, for example, 1 to 5, and it is preferably 1 to 3, more preferably 1 or 2, and still more preferably 1.

The amino group contained in the alkanolamine may be any of a primary amino group (—NH₂), a secondary amino group (>NH), or a tertiary amino group (>N—). However, it is preferable that the alkanolamine has at least one selected from the group consisting of a primary amino group and a secondary amino group, and it is more preferable that any amino group contained in the alkanolamine is a primary amino group or a secondary amino group.

The number of hydroxy groups contained in the aminoalcohol is, for example, 1 to 5, and it is preferably 1 to 3 and more preferably 1 or 2.

Examples of the alkanolamine include 2-aminoethanol, diethanolamine (DEA), triethanolamine (TEA), tri shydroxymethylaminomethane (Tris), 2-(2-aminoethoxy)ethanol, 2-(2-aminoethylamino)ethanol, N,N-dimethylethanolamine, N,N-diethylethanolamine, N-methyldiethanolamine, N-ethyldiethanolamine, N-methylethanolamine, 2-amino-2-methyl-1-propanol, 2-amino-2-methyl-1,3-dipropano1,2-amino-2-ethyl-1,3-dipropanol, and 2-(methylamino)-2-methyl-1-propanol.

Among them, diethanolamine, 2-(2-aminoethylamino)ethanol, 2-(2-aminoethoxy)ethanol, triethanolamine, 2-aminoethanol, N,N-dimethylethanolamine, N,N-diethylethanolamine, N-methyldiethanolamine, N-ethyldiethanolamine, or N-methylethanolamine is preferable, and diethanolamine, 2-(2-aminoethoxy)ethanol, 2-aminoethanol, 2-(2-aminoethylamino)ethanol, N,N-dimethylethanolamine, or N-methylethanolamine is more preferable.

One kind of the alkanolamine may be used alone, or two or more kinds thereof may be used in combination.

From the viewpoint that the Co anticorrosion properties are more excellent, the content of the alkanolamine is preferably 0.1% to 30% by mass, more preferably 0.1% to 15% by mass, still more preferably 0.3% to 10%, and even still more preferably 1% to 10% by mass, with respect to the total mass of the composition.

[Water]

The present composition contains water.

The water is not particularly limited, and distilled water, deionized water, or pure water (ultrapure water) can be used. Pure water is preferable from the viewpoint that it contains almost no impurities and has less influence on a semiconductor substrate in a manufacturing step of the semiconductor substrate.

The pure water is preferably deionized water (DIW) in which inorganic anions, metal ions, and the like are reduced is preferable, and it is more preferably pure water in which the concentration of ions derived from metal atoms of Fe, Co, Na, K, Ca, Cu, Mg, Mn, Li, Al, Cr, Ni, and Zn is reduced. Among the above, in a case of being used in the preparation of the composition, it is preferable that the concentration of ions derived from metal atoms in water is on the order of ppt or less (in one form, the metal content is less than 0.001 ppt by mass). The method of carrying out the adjustment is preferably, purification using a filtration membrane or an ion-exchange membrane or purification by distillation. Examples of the method of carrying out the adjustment include the method described in paragraphs [0074] to [0084] of JP2011-110515A and the method described in JP2007-254168A.

The content of water is not particularly limited; however, it is, for example, 1% to 90% by mass, preferably 5% to 50% by mass, more preferably 10% to 40% by mass, and still more preferably 15% to 35% by mass, with respect to the total mass of the composition.

The water that is used in the embodiment of the present invention is preferably the water prepared as described above. The above-described water is preferably used not only for washing the composition but also for washing the storage container, and it is also preferably used for a manufacturing process of the composition, measurement of components of the composition, and measurement for evaluation of the composition.

[Optional Component]

The component may further contain a component other than the above-described components. Hereinafter, the optional component that may be contained in the composition will be described in detail.

<Component A>

The composition may further contain a component A selected from the group consisting of sulfolene and dipropyl sulfone, and it preferably contains the component A from the viewpoint that the Co anticorrosion properties are more excellent. The term “sulfolene” is a general term that includes all isomers such as 2-sulfolene and 3-sulfolene, and sulfolene includes all isomers.

The composition preferably contains, as the component A, a compound selected from the group consisting of 2-sulfolene and dipropyl sulfone.

The composition may contain one kind of the component A alone or may contain two or more kinds thereof.

In a case where the composition contains the component A, the content of the component A is not particularly limited; however, from the viewpoint that the Co anticorrosion properties are more excellent, it is preferably 10 ppt by mass or more, more preferably 100 ppt by mass or more, and still more preferably 1,000 ppt by mass or more, with respect to the total mass of the composition. The upper limit value thereof is not particularly limited; however, from the viewpoint that the defect suppressiblity is more excellent, it is preferably 1,000 ppm by mass or less, more preferably 100 ppm by mass or less, and still more preferably 10 ppm by mass or less, with respect to the total mass of the composition.

In addition, in a case where the composition contains the component A, the ratio of the content of the azole compound to the content of the component A (content of azole compound/content of component A) is preferably 1.0×10² to 1.0×10¹², more preferably 1.0×10³ to 1.0×10¹⁰, and still more preferably 1.0×10⁴ to 1.0×10⁸, from the viewpoint that the defect suppressiblity is more excellent.

In addition, in a case where the composition contains the component A, the ratio of the content of the aprotic polar solvent to the content of the component A (content of aprotic polar solvent/content of component A) is preferably 1.0×10³ to 1.0×10¹², more preferably 1.0×10⁴ to 1.0×10¹⁰, and still more preferably 1.0×10⁴ to 1.0×10⁹, from the viewpoint that the anticorrosion properties (the W anticorrosion properties) with respect to the metal layer containing tungsten is more excellent.

<Chelating Agent>

The composition may contain a chelating agent.

The chelating agent is a compound having a function of chelating with a metal element. The composition preferably contains a chelating agent since the function of the chelating agent further improves the performance of removing residues such as the etching residue and the ashing residue. In a case where the composition contains a chelating agent, such residues as described above can be removed in a short time, which is preferable from the viewpoint of the anticorrosion properties with respect to the metal layer.

The chelating agent is not particularly limited as long as it is a compound having a function of chelating with a metal element; however, it is preferably a compound having two or more functional groups (coordinating groups) that forms a coordinate bond with the metal element in one molecule.

It is noted that in the present specification, the chelating agent does not include the compound corresponding to the above-described alkanolamine.

Examples of the coordinating group contained in the chelating agent include an acid group and a cationic group. Examples of the acid group include a carboxy group, a phosphonate group, a phosphate group, a sulfo group, and a phenolic hydroxyl group. Examples of the cationic group include an amino group.

The chelating agent contained in the composition preferably has a coordinating group selected from the group consisting of a carboxy group, a phosphonate group, a phosphate group, and an amino group, and it more preferably has a carboxy group.

The chelating agent preferably has a low molecular weight. Specifically, the molecular weight of the chelating agent is preferably 600 or less, more preferably 450 or less, and still more preferably 300 or less. The lower limit thereof is not particularly limited; however, it is preferably 85 or more.

In addition, the number of carbon atoms of the chelating agent is preferably 15 or less, more preferably 12 or less, and still more preferably 8 or less. The lower limit thereof is not particularly limited; however, it is preferably 1 or more.

Examples of the chelating agent include a carboxylic acid-based chelating agent having a carboxy group, a phosphonic acid-based chelating agent having a phosphonate group, a phosphoric acid-based chelating agent having a phosphate group, and a polyamine-based chelating agent having a plurality of amino groups.

(Carboxylic Acid-based Chelating Agent)

The carboxylic acid-based chelating agent is a chelating agent having a carboxy group as a coordinating group in the molecule, and examples thereof include a polycarboxylic acid, an amino polycarboxylic acid, an amino acid, and a hydroxycarboxylic acid.

The polycarboxylic acid is a compound having a plurality of carboxy groups in the molecule. However, the amino polycarboxylic acid described later is not included in the polycarboxylic acid.

Examples of the polycarboxylic acid include citric acid, malonic acid, maleic acid, succinic acid, malic acid, tartaric acid, oxalic acid, glutaric acid, adipic acid, pimelic acid, and sebacic acid.

The amino polycarboxylic acid is a compound having one or more amino groups and a plurality of carboxy groups in the molecule.

The amino polycarboxylic acid is preferably a polyamino polycarboxylic acid having a plurality of amino groups and a plurality of carboxy groups in the molecule. Examples of the polyamino polycarboxylic acid include a mono or polyalkylene polyamine polycarboxylic acid and a polyaminoalkane polycarboxylic acid.

More specific examples of the polyamino polycarboxylic acid include butylenediaminetetraacetic acid, diethylenetriaminepentaacetic acid (DTPA), ethylenediaminetetrapropionic acid, triethylenetetraminehexacetic acid, 1,3-diamino-2-hydroxypropane-N,N,N′,N′-tetraacetic acid, propylenediaminetetraacetic acid, ethylenediaminetetraacetic acid (EDTA), trans-1,2-diaminocyclohexanetetraacetic acid (Cy-DTA), ethylenediaminediacetic acid, ethylenediaminedipropionic acid, and diaminopropanetetraacetic acid, 1,4,7,10-tetraazacyclododecane-tetraacetic acid.

Examples of the amino polycarboxylic acid other than the polyamino polycarboxylic acid include iminodiacetic acid, nitrilotriacetic acid, aspartic acid, and glutamic acid.

Examples of the amino acid include a compound having one or more amino groups and one carboxy group in the molecule.

More specific examples of the amino acid include glycine, serine, α-alanine (2-aminopropionic acid), β-alanine (3-aminopropionic acid), lysine, leucine, isoleucine, cystine, cysteine, ethionine, threonine, tryptophan, tyrosine, valine, histidine, a histidine derivative, asparagine, glutamine, arginine, proline, methionine, phenylalanine, the compounds described in paragraphs [0021] to [0023] of JP2016-086094A, and salts thereof.

It is noted that as the histidine derivative, the compounds described in JP2015-165561A and JP2015-165562A, the contents of which are incorporated herein by reference, can be used. In addition, examples of the salt include alkali metal salts such as a sodium salt and a potassium salt, an ammonium salt, a carbonate, and an acetate.

The hydroxycarboxylic acid is a compound having one carboxy group and one or more hydroxy groups in the molecule.

Examples of the hydroxycarboxylic acid include gluconic acid, heptonic acid, glycolic acid, and lactic acid.

The carboxylic acid-based chelating agent is preferably a polycarboxylic acid or an amino polycarboxylic acid, and more preferably a polycarboxylic acid or a polyamino polycarboxylic acid.

(Phosphonic Acid-based Chelating Agent)

The phosphonic acid-based chelating agent is a chelating agent having at least one phosphonate group as a coordinating group in the molecule. However, a chelating agent having both a phosphonate group and a carboxy group is classified as a carboxylic acid-based chelating agent.

Examples of the phosphonic acid-based chelating agent include ethylidene diphosphonic acid, 1-hydroxyethylidene-1,1′-diphosphonic acid (HEDPO), 1-hydroxypropyridene-1,1′-diphosphonic acid, and 1-hydroxybutylidene-1,1′-diphosphonic acid, ethylaminobis(methylenephosphonic acid), dodecylaminobis(methylenephosphonic acid), nitrilotris(methylenephosphonic acid) (NTPO), ethylenediaminebis(methylenephosphonic acid) (EDDPO), 1,3-propylenediaminebis(methylenephosphonic acid), ethylenediaminetetrakis(methylenephosphonic acid) (EDTPO), ethylenediaminetetrakis(ethylenephosphonic acid), 1,3-propylenediaminetetrakis(methylenephosphonic acid) (PDTMP), 1,2-diaminopropanetetrakis(methylenephosphonic acid), 1,6-hexamethylenediaminetetrakis(methylenephosphonic acid), diethylenetriaminepentakis(methylenephosphonic acid) (DEPPO), diethylenetriaminepentakis(ethylenephosphonic acid), triethylenetetraminehexakis(methylenephosphonic acid), and triethylenetetraminehexakis(ethylenephosphonic acid).

As the phosphonic acid-based chelating agent that is used in the composition, not only the above-described compounds but also the compounds described in paragraphs [0026] to [0036] of WO2018/020878A and the compounds ((co)polymers) described in paragraphs [0031] to [0046] of WO2018/030006A can be used, the contents of which are incorporated herein by reference.

The number of phosphonate groups contained in the phosphonic acid-based chelating agent is preferably 2 to 5, more preferably 2 to 4, and still more preferably 2 or 3.

The phosphonic acid-based chelating agent preferably has 12 or fewer carbon atoms, more preferably has 10 or fewer carbon atoms, and still more preferably 8 or fewer carbon atoms. The lower limit thereof is not particularly limited; however, it is preferably 1 or more.

The phosphonic acid-based chelating agent is more preferably HEDPO, NTPO, EDTPO, or DEPPO, and still more preferably EDTPO.

One kind of the phosphonic acid-based chelating agent may be used alone, or two or more kinds thereof may be used in combination.

(Phosphoric Acid-based Chelating Agent)

Examples of the phosphoric acid-based chelating agent include condensed phosphoric acid and a salt thereof, and more specific examples thereof include pyrrolic acid, tripolyphosphoric acid, hexametaphosphoric acid, and salts thereof.

(Polyamine-based Chelating Agent)

The polyamine-based chelating agent is a chelating agent having only a plurality of amino groups as coordinating groups in the molecule.

Examples of the polyamine-based chelating agent include lower alkylenediamines such as ethylenediamine (EDA), 1,3-propanediamine (PDA), 1,2-propanediamine, 1,3-butanediamine, and 1,4-butanediamine, and polyalkylpolyamines such as diethylenetriamine (DETA), triethylenetetramine (TETA), bis(aminopropyl)ethylenediamine (BAPEDA), and tetraethylenepentamine.

Among them, a lower alkylenediamine is preferable, and 1,4-butanediamine is more preferable.

Examples of the polyamine-based chelating agent other than those described above include at least one biguanide compound selected from the group consisting of a compound having a biguanide group and a salt thereof. The number of biguanide groups contained in the biguanide compound is not particularly limited, and a plurality of biguanide groups can be contained therein.

As biguanide compounds, the compounds described in paragraphs [0034] to [0055] of JP2017-504190A can also be used, and the content described in this document is incorporated in the present specification.

Examples of the compound having a biguanide group include ethylene dibiguanide, propylene dibiguanide, tetramethylene dibiguanide, pentamethylene dibiguanide, hexamethylene dibiguanide, heptamethylene dibiguanide, octamethylene dibiguanide, 1,1′-hexamethylenebis(5-(p-chlorophenyl)biguanide) (chlorhexidine), 2-(benzyloxymethyl)pentane-1,5-bis (5-hexylbiguanide), 2-(phenylthiomethyl pentane-1,5-bis(5-phenetylbiguanide), 3-(phenylthio)hexane-1,6-bis(5-hexylbiguanide), 3-(phenylthio)hexane-1,6-bis(5-cyclohexylbiguanide), 3-(benzylthio)hexane-1,6-bis(5-hexylbiguanide), and 3-(benzylthio)hexane-1,6-bis(5-cyclohexylbiguanide).

The salt of the compound having a biguanide group is preferably a hydrochloride salt, an acetate salt, or a gluconate salt.

Examples of the chelating agent other than those described above include a compound represented by Formula (A) and a compound represented by Formula (B).

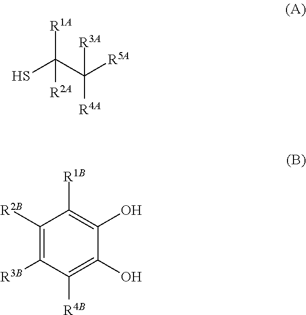

In Formula (A), R^{1A} to R^{5A} each independently represent a hydrogen atom, a substituted or unsubstituted hydrocarbon group, a hydroxy group, a carboxy group, or a substituted or unsubstituted amino group. However, a structure of Formula (A) includes at least one group selected from the hydroxy group, the carboxy group, or the substituted or unsubstituted amino group,

In Formula (B), R^{1B} to R^{4B} each independently represent a hydrogen atom or a substituted or unsubstituted hydrocarbon group.

Examples of the compound represented by Formula (A) include 1-thioglycerol and thiomaleic acid.

Examples of the compound represented by Formula (B) include catechol and t-butyl catechol.

The chelating agent is preferably a carboxylic acid-based chelating agent or a phosphonic acid-based chelating agent, more preferably a carboxylic acid-based chelating agent, still more preferably a polycarboxylic acid or an amino polycarboxylic acid, and particularly preferably a polyamino polycarboxylic acid or a polycarboxylic acid.

One kind of the chelating agent may be used alone, or two or more kinds thereof may be used in combination.

The coordinating group contained in the chelating agent differs in the specificity of the metal to be adsorbed, depending on the kind thereof, and thus it is preferable that the composition contains a combination of two or more chelating agents having coordinating groups different from each other from the viewpoint of more excellent removability of residues including a plurality of metals.

In a case where the composition contains a combination of two or more kinds of the above-described chelating agents, the mass ratio of the contents of other chelating agents to the content of the one kind of chelating agent is preferably 0.01 to 100, and preferably 0.1 to 10.

In a case where the composition contains a chelating agent, from the viewpoint of more excellent residue removability, the content of the chelating agent is preferably 0.01% to 10% by mass, more preferably 0.05% to 5% by mass, and still more preferably 0.1% to 3%, with respect to the total mass of the composition.

In addition, in a case where the residue contains a large amount of metal, for example, in a case where an object to be washed is a dry etching residue, the chelating agent has an effect of further improving the residue removability of the composition. From this point, it is preferable that the composition containing the chelating agent is used for treating such an object to be washed.

<Basic Compound>

The composition may contain a basic compound.

The basic compound is intended to be a compound, where the pH of a solution of the compound exceeds 7 in a case of being dissolved in water. The basic compound has a function as a pH adjusting agent for adjusting the pH of the composition.

The basic compound is not particularly limited, and examples thereof include ammonium hydroxide, an amine compound (however, the azole compound, the alkanolamine, and the compound contained in the chelating agent are excluded), and a quaternary ammonium compound.

(Ammonium Hydroxide)

The composition may contain ammonium hydroxide (NH₄OH) as the basic compound.

In a case where the composition contains ammonium hydroxide, the content of the ammonium hydroxide is not particularly limited; however, it is preferably 0.01% to 10% by mass, and more preferably 0.05% to 5.0% by mass with respect to the total mass of the composition.

(Amine Compound)

In the present specification, the amine compound is a compound having an amino group in the molecule, where the amine compound is intended to be a compound not included in the azole compound, the alkanolamine, or the chelating agent.

Examples of the amine compound include a primary amine having a primary amino group (—NH₂) in the molecule, a secondary amine having a secondary amino group (>NH) in the molecule, a tertiary amine having a tertiary amino group (>N—) in the molecule, and a salt thereof.

Examples of the salt of the amine compound include a salt of an inorganic acid, in which at least one non-metal selected from the group consisting of Cl, S, N, and P is bonded to hydrogen, where a hydrochloride, a sulfate, or a nitrate is preferable.

In addition, the amine compound is preferably a water-soluble amine, where an amount of 50 g or more of the amine compound can be dissolved in 1 L of water.

Examples of the amine compound include an alicyclic amine compound, a hydroxylamine compound, and another amine compound other than these compounds.

The alicyclic amine compound is intended to be a compound having an alicyclic ring(non-aromatic ring) structure in the molecule among the amine compounds.

Examples of the alicyclic amine compound include 1,8-diazabicyclo[5.4.0]-7-undecene (DBU), ε-caprolactam, the following compound 1, the following compound 2, the following compound 3,1,4-diazabicyclo[2.2.2]octane (DABCO), tetrahydrofurfurylamine, N-(2-aminoethyl)piperazine, hydroxyethylpiperazine, piperazine, 2-methylpiperazine, trans-2,5-dimethylpiperazine, cis-2,6-dimethylpiperazine, 2-piperidinemethanol, cyclohexylamine, and 1,5-diazabicyclo[4,3,0]-5-nonene.

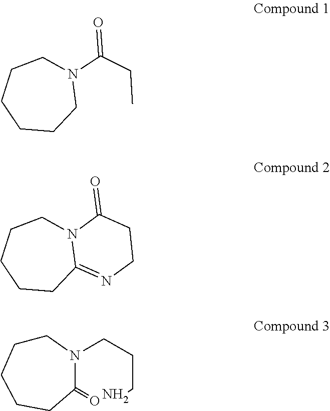

The hydroxylamine compound is at least one compound selected from the group consisting of hydroxylamine (NH₂OH), a hydroxylamine derivative, and a salt thereof.

The hydroxylamine derivative is not particularly limited; however, examples thereof include O-methylhydroxylamine, O-ethylhydroxylamine, N-methylhydroxylamine, N,N-dimethylhydroxylamine, N, O-dimethylhydroxylamine, N-ethylhydroxylamine, N,N-diethylhydroxylamine, N, O-diethylhydroxylamine, O,N,N-trimethylhydroxylamine, N,N-dicarboxyethylhydroxylamine, and N,N-disulfoethylhydroxylamine.

Examples of the salts of the hydroxylamine and the hydroxylamine derivative include inorganic acid salts and organic acid salts, where an inorganic acid salt formed by bonding a non-metal atom such as Cl, S, N, or P to a hydrogen atom is preferable, and a salt of any acid of hydrochloric acid, sulfuric acid, or nitric acid is more preferable.

Among the amine compounds, examples of the primary amine other than the alicyclic amine compound and the hydroxylamine compound include methylamine, ethylamine, propylamine, butylamine, pentylamine, methoxyethylamine, and methoxypropylamine.

Examples of the secondary amine other than the alicyclic amine compound and the hydroxylamine compound include dimethylamine, diethylamine, dipropylamine, and dibutylamine (DBA).

Examples of the tertiary amine other than the alicyclic amine compound and the hydroxylamine compound include trimethylamine, triethylamine, and tributylamine (TBA).

One kind of the amine compound may be used alone, or two or more kinds thereof may be used in combination.

In a case where the composition contains an amine compound, the content thereof is not particularly limited; however, it is preferably 0.01% to 30% by mass and more preferably 0.1% to 20% by mass with respect to the total mass of the composition.

(Quaternary Ammonium Compound)

The composition may include, as a removing agent, a quaternary ammonium compound which is a compound having one quaternary ammonium cation or a salt thereof in the molecule.

The quaternary ammonium compound is not particularly limited as long as it is a compound having one quaternary ammonium cation in which a nitrogen atom is substituted with four hydrocarbon groups (preferably an alkyl group), or a salt thereof.

Examples of the quaternary ammonium compound include a quaternary ammonium hydroxide, a quaternary ammonium fluoride, a quaternary ammonium bromide, a quaternary ammonium iodide, a quaternary ammonium acetate, and a quaternary ammonium carbonate.

The quaternary ammonium compound is preferably a quaternary ammonium hydroxide and more preferably a compound represented by Formula (a1).

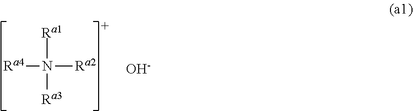

In Formula (a1), R^{a1} to R^{a4} each independently represent an alkyl group having 1 to 16 carbon atoms, an aryl group having 6 to 16 carbon atoms, an aralkyl group having 7 to 16 carbon atoms, or a hydroxyalkyl group having 1 to 16 carbon atoms. At least two of R^{a1} to R^{a4} may be bonded to each other to form a cyclic structure.

The alkyl group may be either linear, branched, or cyclic.

Examples of the compound represented by Formula (a1) include tetramethylammonium hydroxide (TMAH), tetraethylammonium hydroxide (TEAH), tetrapropylammonium hydroxide, tetrabutylammonium hydroxide (TBAH), methyltripropylammonium hydroxide, methyltributylammonium hydroxide, ethyltrimethylammonium hydroxide, dimethyl diethylammonium hydroxide, benzyltrimethylammonium hydroxide (BzTMAH), hexadecyltrimethylammonium hydroxide, (2-hydroxyethyl)trimethylammonium, and spiro-(1,1′)-bipyrrolidinium hydroxide.

One kind of the quaternary ammonium compound may be used alone, or two or more kinds thereof may be used in combination.

In a case where the composition contains a quaternary ammonium compound, the content thereof is preferably 0.01% to 30% by mass and more preferably 0.1% to 20% by mass with respect to the total mass of the composition.

One kind of the basic compound may be used alone, or two or more kinds thereof may be used in combination.

In a case where the composition contains a basic compound, the content of the basic compound is preferably 0.01% to 30% by mass and more preferably 0.1% to 20% by mass with respect to the total mass of the composition.

<Acidic Compound>

The composition may contain an acidic compound as a pH adjusting agent.

The acidic compound may be an inorganic acid or may be an organic acid (however, the above-described chelating agent is excluded).

Examples of the inorganic acid include sulfuric acid, hydrochloric acid, acetic acid, nitric acid, and phosphoric acid, where sulfuric acid, hydrochloric acid, or acetic acid is preferable. Examples of the organic acid include lower (1 to 4 carbon atoms) aliphatic monocarboxylic acids such as formic acid, acetic acid, propionic acid, and butyric acid. In addition, the above-described chelating agent may also serve as an acidic compound.

One kind of the acidic compound may be used alone, or two or more kinds thereof may be used in combination.

The kind and content of the acidic compound may be adjusted by appropriately selecting the kind and adjusting the content so that the pH of the composition is within a range described below.

<Fluorine-Containing Compound>

The composition may contain a fluorine-containing compound.

Examples of the fluorine-containing compound include hydrofluoric acid (fluorinated acid), ammonium fluoride, tetramethylammonium fluoride, and tetrabutylammonium fluoride, where hydrofluoric acid is preferable.

One kind of the fluorine-containing compound may be used alone, or two or more kinds thereof may be used in combination.

In a case where the composition contains a fluorine-containing compound, the content thereof is preferably 0.01% to 5.0% by mass with respect to the total mass of the composition.

<Metal Component>

The composition may contain a metal component.

Examples of the metal component include metal particles and metal ions. For example, in a case of being referred to as the content of the metal component, it indicates the total content of metal particles and metal ions. The composition may contain either metal particles or metal ions, or it may contain both metal particles and metal ions.

Examples of the metal atom contained in the metal component include an metal atom selected from the group consisting of Ag, Al, As, Au, Ba, Ca, Cd, Co, Cr, Cu, Fe, Ga, Ge, K, Li, Mg, Mn, Mo, Na, Ni, Pb, Sn, Sr, Ti, and Zn.

The metal component may contain one kind of metal atom or two or more kinds thereof.

The metal particle may be a single body or an alloy or may be present in a form in which the metal is associated with an organic substance.

The metal component may be a metal component unavoidably contained in each component (raw material) contained in the composition or may be a metal component unavoidably contained during the production, storage, and/or transfer of the composition, and it may be added intentionally.

In a case where the composition contains a metal component, the content of the metal component is 0.01 ppt by mass to 10 ppm by mass with respect to the total mass of the composition in a large number of cases, and it is preferably 0.1 ppt by mass to 1 ppm by mass and more preferably 0.1 ppt by mass to 100 mass ppb.

The kind and content of the metal component in the composition can be measured by an inductively coupled plasma mass spectrometry (ICP-MS).

In the ICP-MS method, the content of the metal component to be measured is measured regardless of the existence form thereof. As a result, the total mass of metal particles to be measured and metal ions is quantified as the content of the metal component.

Regarding the measurement with the ICP-MS method, it is possible to use an Agilent 8800 triple quadrupole ICP-MS (inductively coupled plasma mass spectrometry, for semiconductor analysis, option #200) and Agilent 8900, manufactured by Agilent Technologies, Inc., and NexION 350S manufactured by PerkinElmer, Inc.

The method of adjusting the content of each metal component in the composition is not particularly limited. For example, the content of the metal component in the composition can be reduced by carrying out a known treatment of removing a metal from the composition and/or from a raw material containing each component that is used in the preparation of the composition. In addition, the content of the metal component in the composition can be increased by adding a compound containing metal ions to the composition.

<Anticorrosive Agent>

The composition preferably contains an anticorrosive agent.

The anticorrosive agent has a function of preventing corrosion of a metal layer due to over-etching or the like, by coordinating and forming a film on the surface of the metal layer (particularly, the W-containing layer or the Co-containing layer) serving as wires of a semiconductor device.

It is noted that in the present specification, the above-described azole compound and chelating agent (compound having chelating ability) are not included in the anticorrosive agent.

Examples of the anticorrosive agent include tritolyl phosphate, adenine, cytosine, guanine, thymine, a phosphate inhibitor, propanethiol, silanes, benzohydroxamic acids, a heterocyclic nitrogen inhibitor, ascorbic acid, thiourea, 1,1,3,3-tetramethylurea, urea, urea derivatives, uric acid, potassiumethylxanthogenate, dodecylphosphonic acid, boric acid, 2,3,5-trimethylpyrazine, 2-ethyl-3,5-dimethylpyrazine, quinoxaline, acetylpyrrole, pyridazine, histadine, pyrazine, glutathione (reduced form), thiophene, mercaptopyridine N-oxide, thiamine HCl, tetraethylthiuram disulfide, and phenol.

Examples of the anticorrosive agent include a substituted or unsubstituted tetrazole.

Examples of the substituted or unsubstituted tetrazole include an unsubstituted tetrazole and a tetrazole having, as a substituent, a hydroxy group, a carboxy group, or a substituted or unsubstituted amino group. Here, the substituent in a case where the amino group is substituted is preferably an alkyl group having 1 to 6 carbon atoms and more preferably an alkyl group having 1 to 3 carbon atoms.

One kind of anticorrosive agent may be used alone, or two or more kinds thereof may be used in combination.

In a case where the composition contains an anticorrosive agent, the content of the anticorrosive agent in the composition is preferably 0.01% to 5% by mass, more preferably 0.05% to 5% by mass, and still more preferably 0.1% to 3% by mass with respect to the total mass of the composition.

As the anticorrosive agent, an anticorrosive agent of a high-purity grade is preferably used, which is more preferably used by being further purified.

The method of purifying the anticorrosive agent is not particularly limited. However, for example, a known method such as filtration, ion exchange, distillation, adsorption purification, recrystallization, reprecipitation, sublimation, or purification using a column is used, and this method can be also applied in combination.

The composition may contain an additive other than the above components. Examples of the additive include a surfactant, an antifoaming agent, a rust inhibitor, and a preservative.

[Physical Properties of Composition]

<pH>

The present composition is preferably used at a pH of 7 or higher.

The pH of the present composition is preferably 9 to 11. In a case where the pH is 9 to 11, a composition having more excellent anticorrosion properties with respect to a metal layer formed of a wiring line material such as Co and W is obtained.

The pH of the composition is preferably 9.2 to 11 and more preferably 9.5 to 11 from the viewpoint that the Co anticorrosion properties and the W anticorrosion properties are more excellent.

The pH of the composition is a value obtained by carrying out the measurement at 25° C. using a known pH meter.

<Coarse Particle>

It is preferable that the composition is substantially free of coarse particles.

The coarse particles refer to particles having a diameter of 0.2 μm or more in a case where the shape of the particles is regarded as a sphere. In addition, a case of being substantially free of coarse particles refers to that ten or fewer particles of 0.2 μm or more are present in 1 mL of the composition in a case where the composition is subjected to measurement using a commercially available measuring device in the light scattering type in-liquid particle measuring method.

It is noted that the coarse particles contained in the composition are particles or the like of dirt, dust, organic solids, inorganic solids, and the like contained as impurities in raw materials, and particles of dirt, dust, and organic solids, and inorganic solids brought in as contaminants during the preparation of the composition, which correspond to the particles that are finally present as particles without being dissolved in the composition.

The amount of the coarse particles present in the composition can be measured in the liquid phase using a commercially available measuring device in a light scattering type in-liquid particle measuring method using a laser as a light source.

Examples of the method of removing coarse particles include a purification treatment such as filtering.

[Kit and Concentrated Solution]

The raw materials of the composition may be divided into a plurality of parts to be used as a kit for preparing the composition. Examples of the kit for preparing the composition include a kit that includes a first liquid containing at least an azole compound and an alkanolamine and a second liquid containing at least an aprotic polar solvent (hereinafter, also described as a “kit A”).

The first liquid of the kit A may contain a component other than the azole compound and the alkanolamine; however, it preferably does not contain an aprotic polar solvent. In addition, the second liquid of the kit A may contain a component other than the aprotic polar solvent; however, it preferably does not contain any of the azole compound or the alkanolamine.

The content of each component included in the first liquid and the second liquid provided in the kit is not particularly limited; however, the content of each component in the composition prepared by mixing the first liquid and the second liquid is preferably an amount corresponding to the preferred amount described above.

The pH of each of the first liquid and the second liquid provided in the kit is not particularly limited, and it suffices that the pH is adjusted so that the pH of the composition prepared by mixing the first liquid and the second liquid is included in the above-described range.

In addition, the composition may be prepared as a concentrated solution. In this case, it can be diluted with a diluent liquid at the time of use. The diluent liquid is not particularly limited; however, examples thereof include a diluent liquid consisting of alcohol, an aprotic polar solvent, water, or a mixed solution thereof. That is, the kit for preparing the composition may be a kit including the composition in the form of a concentrated solution and the diluent liquid.

[Use Application]

Next, the use application of the composition involved in the above-described embodiment will be described.

The composition is a composition for a semiconductor device. In the present specification, “for a semiconductor device” means that it is used in the manufacture of a semiconductor device. The composition can be used in any step for manufacturing a semiconductor device and can be used, for example, for treating an insulating film, a resist, an antireflection film, an etching residue, an ashing residue, and the like, which are present on a substrate. It is noted that in the present specification, the etching residue and the ashing residue are collectively referred to as residues. In addition, the composition may be used for treating a substrate after chemical mechanical polishing or may be used as an etchant.

Specifically, the composition can be used as a treatment fluid such as a pre-wet liquid to be applied on a substrate to improve the coatability of an actinic ray-sensitive or radiation-sensitive composition before the step of forming a resist film using the composition, a composition that is used for removing residues that have adhered on a metal layer, a solution (for example, a removal liquid or a stripper) that is used for removing various resist films for pattern formation, or a solution (for example, a removal liquid or a stripper) that is used for removing a permanent film (for example, a color filter, a transparent insulating film, or a lens made of a resin) from a semiconductor substrate. It is noted that since the semiconductor substrate after the removal of the permanent film may be used again for the manufacture of the semiconductor device, the removal of the permanent film is included in the manufacturing step of the semiconductor device.

In addition, the composition can also be used as a composition that is used for removing residues such as metal impurities or fine particles from a substrate after chemical mechanical polishing.

In addition, the composition can also be used as an etchant for metal oxides such as cobalt oxide and copper oxide (including a composite oxide consisting of a plurality of metal oxides).

Among the use applications, in particular, it can be suitably used as a composition for removing residues that have adhered to metal layers (among them, particularly a Co-containing layer or a W-containing layer).

The composition may be used in only one use application or two or more of use applications among the above-described use applications.

[Production Method for Composition]

<Composition Preparation Step>

The production method for the composition is not particularly limited, and a known production method can be used. Examples of the production method for the above-described composition include a method having at least a composition preparation step of mixing the above-described components to prepare the composition.

In the composition preparation step, the order in which the respective components are mixed is not particularly limited. It is preferable that each of the liquids provided in the kit and the concentrated solution is also produced according to the same method as described above.

The method for producing the kit is not particularly limited. For example, after preparing the first liquid and the second liquid described above, the first liquid and the second liquid are respectively accommodated in containers different from each other to produce a kit for preparing the composition.

<Metal Removal Step>

Prior to use in the composition preparation step, it is preferable to subject each component to a metal removal step of removing a metal from a raw material containing each component to obtain a purified substance containing each component. In a case of subjecting each component to a metal removal step and preparing a composition using each component contained in the obtained purified substance, it is possible to further reduce the content of the metal component contained in the composition.

A method of removing a metal from a raw material (hereinafter, also referred to as a “purification target substance”) containing each component is not particularly limited, and known methods such as a method of passing a purification target substance through at least one resin selected from the group consisting of a chelating resin and an ion exchange resin and a method of passing a purification target substance through a metal ion adsorption filter can be applied thereto.

A component to be subjected to the metal removal step is not particularly limited as long as it is a component contained in the above composition (however, the metal component is excluded). In a case where the composition contains a chelating agent, the content of the metal component contained in a raw material containing the chelating agent tends to be large as compared with those of other components, and thus it is more preferable to prepare the composition by using a purified substance containing a chelating agent, which is obtained by subjecting a raw material containing a chelating agent to the metal removal step.

The purification target substance to be subjected to the metal removal step may contain a compound other than the purification object, where a solvent is preferably contained. Examples of the solvent include water and an organic solvent, where water is preferable.

The content of the purification object in the purification target substance can be appropriately adjusted according to the kind of the object and the specific metal removal treatment, and it may be, for example, 1% to 100% by mass with respect to the total mass of the purification target substance, where 10% to 50% by mass is preferable.

The method of passing a purification target substance through at least one resin selected from the group consisting of a chelating resin and an ion exchange resin is not particularly limited, however, examples thereof include a method of passing a purification target substance through a container filled with a chelating resin and/or an ion exchange resin.

The chelating resin and/or the ion exchange resin, through which the purification target substance is passed, may be used alone, or two or more kinds thereof may be used. In addition, the purification target substance may be passed twice or more times through the same chelating resin and/or ion exchange resin.

In the metal removal step, both the chelating resin and the ion exchange resin may be used. In that case, the chelating resin and the ion exchange resin may be used in a double bed or a mixed bed.

The container is not particularly limited as long as it can be filled with a chelating resin and/or an ion exchange resin and can pass a purification target substance through the chelating resin and/or the ion exchange resin, with which the container filled, and examples thereof include a column, a cartridge, and a filling tower.

Examples of the ion exchange resin that is used in the metal removal step include a cation exchange resin and an anion exchange resin. The cation exchange resin may be used in a single bed, or the cation exchange resin and the anion exchange resin may be used in a double bed or a mixed bed.

As the cation exchange resin, a known cation exchange resin can be used, and examples thereof include a sulfonic acid type cation exchange resin and a carboxylic acid type cation exchange resin. The material of the cation exchange resin is not particularly limited; however, it is preferably a gel-type cation exchange resin.

As the cation exchange resin, a commercially available product can be used, examples of thereof include Amberlite (registered trade name, the same applies hereinafter) IR-124, Amberlite IR-120B, Amberlite IR-200CT, Orlite (registered trade name, the same applies hereinafter) DS-1, and, Orlite DS-4 (all manufactured by ORGANO CORPORATION); Duolite (registered trade name, the same applies hereinafter) C20J, Duolite C20LF, Duolite C255LFH, and Duolite C-433LF (all manufactured by Sumika Chemtex Co., Ltd.); DIAION (registered trade name, the same applies hereinafter) SK-110, DIAION SK1B, and DIAION SK1BH (all, manufactured by Mitsubishi Chemical Corporation); and Purolite (registered trade name, the same applies hereinafter) 5957 and Purolite 5985 (all manufactured by Purolite Co., Ltd.).

The chelating resin is not particularly limited as long as it is a resin that has a chelating group having a function of chelating with a metal.

Examples of the chelating group include an aminophosphonate group such as an iminodiacetate group, an iminopropionate group, or an aminomethylenephosphonate group (—NH—CH₃—PO₃H₂), a polyamine group, a glucamine group such as an N-methylglucamine group, an aminocarboxy group, a dithiocarbamate group, a thiol group, an amidoxime group, and a pyridine group, where an iminodiacetate group or an aminophosphonate group is preferable, and an aminophosphonate group is more preferable.

These chelating groups may form a salt together with a counter ion; however, it preferably does not form a salt from the viewpoint that the metal content can be further reduced. That is, the chelating resin is preferably an H-type chelating resin. The H-type chelating resin is obtained by bringing a metal ion-type chelating resin such as an Na-type, a Ca-type, or an Mg-type into contact with a mineral acid.

The base substance of the chelating resin is not particularly limited, and examples thereof include a styrene-divinylbenzene copolymer and a styrene-ethylstyrene-divinylbenzene copolymer.

As the chelating resin, a commercially available product can be used, and examples thereof include Duolite ES371N, Duolite C467, Duolite C747UPS, SUMICHELATE (registered trade name, the same applies hereinafter) MC760, SUMICHELATE MC230, SUMICHELATE MC300, SUMICHELATE MC850, SUMICHELATE MC640, SUMICHELATE MC900, and SUMICHELATE MC960 (all manufactured by Sumika Chemtex Co., Ltd.); Purolite 5106, Purolite 5910, Purolite 5914, Purolite 5920, Purolite 5930, Purolite 5950, Purolite 5957, and Purolite 5985 (all manufactured by Purolite Co., Ltd.); and Orlite DS-21, Amberlite IRC748, and Amberlite IRC747 (all manufactured by ORGANO CORPORATION).

In a case where the composition contains a chelating agent, from the viewpoint that the content of the metal component in the composition can be further reduced, the metal removal step to which a raw material containing the chelating agent is subjected preferably includes a step of passing a purification target substance through at least one resin selected from the group consisting of a chelating resin and an ion exchange resin, and more preferably include a step of passing a purification target substance through a chelating resin. Among the above, from the viewpoint that the contents of Ca and/or Zn contained in the raw material containing the chelating agent can be further reduced, it is more preferable to include a step of passing a purification target substance through a chelating resin having an aminophosphonate group.

Examples of the commercially available products of the chelating resin having an aminophosphonate group include Duolite C467, Duolite C747UPS, SUMICHELATE MC960, Purolite 5950, Orlite DS-21, and Amberlite IRC747, where Orlite DS-21 is preferable.

It is noted that Orlite DS-21 is an H-type chelating resin obtained by introducing an aminomethylphosphonate group as a chelating group into a base material consisting of a styrene-ethylstyrene-divinylbenzene copolymer, and it is commercially available in a state containing 30% to 45% by mass of the chelating resin and 55% to 70% by mass of water.

The conditions for passing a purification target substance through the ion exchange resin are not particularly limited, and the conditions according to the known method may be adopted.

The space velocity (SV) at the time when a purification target substance passes while coming into contact with the ion exchange resin is preferably 1 to 20 and more preferably 1 to 10.

The temperature of a purification target substance that comes into contact with the ion exchange resin is preferably 10° C. to 40° C. and more preferably 15° C. to 30° C.

As the metal removal step of a purification target substance, the adsorption purification treatment step of a metal component using silicon carbide, described in WO2012/043496A, may be carried out, and this description is incorporated in the present specification.

In addition, as the metal removal step of a purification target substance, metal particles contained in the purification target substance may be removed by using a filter that is mentioned as a filter that is used in the filtration step described later.

The metal removed from the purification target substance by the metal removal step is not particularly limited, and examples thereof include metals such as Li, Na, Mg, Al, K, Ca, Cr, Mn, Fe, Ni, Zn, and Pb. In the purified substance obtained by the metal removal step, the above-described metal content is reduced as compared with the purification target substance.

The content of the metal in the purified substance is not particularly limited. However, for example, the ratio of the content of the metal component per each metal element to the content of the chelating agent in the purified substance containing the chelating agent is 1.0×10⁻⁶ or less, more preferably 1.0×10⁻⁷ or less, and still more preferably 1.0×10⁻⁸ or less in terms of mass ratio.

In addition, in the purified substance containing a chelating agent, which has been obtained by the metal removal step, the ratio of the content of the Ca component to the content of the Na component is preferably 1.0 or more by mass (the content of the Ca component is preferably larger than the content of the Na component), more preferably 1.1 or more, and still more preferably 1.2 or more in terms of mass ratio. The upper limit thereof is not particularly limited; however, the ratio of the content of the Ca component to the content of the Na component is preferably 50 or less in terms of mass ratio.

It is noted that the kind and content of the metal in the purification target substance and the purified substance can be measured according to the method described as the measuring method for the kind and content of the metal component in the composition.

<Filtration Step>

It is preferable that the production method includes a filtration step of filtering a liquid in order to remove foreign matters, coarse particles, and the like from the liquid.

The filtration method is not particularly limited, and a known filtration method can be used. Among the above, filtering using a filter is preferable.

The filter that is used for filtering can be used without particular limitation as long as it is a filter that is conventionally used in the use application of filtering and the like. Examples of the material constituting the filter include a fluororesin such as polytetrafluoroethylene (PTFE), a polyamide-based resin such as nylon, a polyolefin-based resin (having a high density and an ultrahigh molecular weight) such as polyethylene or polypropylene (PP), and polyaryl sulfone. Among them, a polyamide-based resin, PTFE, polypropylene (including high-density polypropylene), and polyaryl sulfone are preferable.

In a case of using a filter formed from these materials, it is possible to more effectively remove foreign matters having high polarity, which are likely to cause defects, from the composition.

The lower limit value of the critical surface tension of the filter is preferably 70 mN/m or more, and the upper limit value thereof is preferably 95 mN/m or less. In particular, the critical surface tension of the filter is preferably 75 to 85 mN/m.

It is noted that the value of the critical surface tension is a nominal value of a manufacturer. In a case of using a filter having a critical surface tension in the above range, it is possible to more effectively remove foreign matters having high polarity, which are likely to cause defects, from the composition.

The pore diameter of the filter is preferably about 0.001 to 1.0 more preferably about 0.02 to 0.5 and still more preferably about 0.01 to 0.1 In a case of setting the pore diameter of the filter within the above range, it is possible to reliably remove fine foreign matters contained in the composition while suppressing filtration clogging.

In a case of using a filter, different filters may be combined. In this case, filtering with a first filter may be carried out only once or may be carried out twice or more times. In a case where different filters are combined and filtering is carried out two or more times, the kinds of filters may be the same or different from each other; however, the kinds of filters are preferably different from each other. Typically, it is preferable that at least one of the pore diameter or the constitutional material is different between the first filter and the second filter.

It is preferable that the pore diameters of the second and subsequent filtering are equal to or smaller than the pore diameter of the first filtering. In addition, the first filters having different pore diameters within the above range may be combined. With regard to the pore diameters herein, reference can be made to nominal values of filter manufacturers. A commercial filter can be selected from various filters provided by, for example, Nihon Pall Ltd., Advantec Toyo Kaisha, Ltd., Nihon Entegris K. K. (formerly Nippon Microlith Co., Ltd.), and Kitz Micro Filter Corporation. In addition, the following filters can also be used: “P-nylon filter (pore diameter: 0.02 μm, critical surface tension: 77 mN/m)” made of polyamide (manufactured by Nihon Pall Ltd.); “PE clean filter (pore diameter: 0.02 μm)” made of high-density polyethylene (manufactured by Nihon Pall Ltd.); and “PE clean filter (pore diameter: 0.01 μm)” made of high-density polyethylene (manufactured by Nihon Pall Ltd.).

As a second filter, a filter formed of the same material as that of the first filter can be used. A filter having the same pore diameter as that of the first filter described above can be used. In a case where the second filter having a pore diameter smaller than that of the first filter is used, the ratio of the pore diameter of the second filter to the pore diameter of the first filter (the pore diameter of the second filter/the pore diameter of the first filter) is preferably 0.01 to 0.99, is more preferably 0.1 to 0.9, and is still more preferably 0.3 to 0.9. In a case of setting the pore diameter of the second filter within the above range, fine foreign matters mixed in the composition are more reliably removed.

For example, filtering with the first filter may be carried out with a mixed liquid containing a part of components of the composition, and after mixing the remaining components with the mixed liquid to prepare the composition, the filtering with the second filter may be carried out.

In addition, it is preferable that the filter to be used is treated before filtering the composition. The liquid that is used for this treatment is not particularly limited; however, it is preferably the composition or a liquid containing components that are contained in the concentrated solution and the composition.

In a case of carrying out filtering, the upper limit value of the temperature during filtering is preferably room temperature (25° C.) or lower, more preferably 23° C. or lower, and still more preferably 20° C. or lower. The lower limit value of the temperature at the time of filtering is preferably 0° C. or higher, more preferably 5° C. or higher, and still more preferably 10° C. or higher.

In the filtering, particulate foreign matters and/or impurities can be removed. However, in a case where the filtering is carried out at the above temperature, the amount of the particulate foreign matters and/or impurities dissolved in the composition is reduced, and thus the filtering is carried out more efficiently.

<Destaticization Step>

The above-described production method may further include a destaticization step of destaticizing at least one selected from the group consisting of a composition, a concentrated solution, and a kit. A specific method for destaticization will be described later.

It is preferable that all the steps involved in the production method are carried out in a clean room. It is preferable that the clean room satisfies 14644-1 clean room standards. It is preferable that the clean room satisfies any one of the International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

<Container>

The container that accommodates the above-described composition, concentrated solution, or kit is not particularly limited as long as the corrosiveness due to the liquid does not cause a problem, and a known container can be used.

The container is preferably a container for a use application in a semiconductor, which has high internal cleanliness and hardly causes elution of impurities.

Examples of the commercially available product of the container include “CLEAN BOTTLE” series manufactured by AICELLO CHEMICAL Co., Ltd. and “PURE BOTTLE” manufactured by KODAMA PLASTICS Co., Ltd. In addition, for the intended purpose of preventing the mixing (contamination) of raw materials and impurities into the chemical liquid, it is also preferable to use a multi-layer container in which an inner wall of the container has a six-layer structure consisting of six kinds of resins and a multi-layer container in which an inner wall of the container has a seven-layer structure consisting of six kinds of resins. Examples of these containers include a container described in JP2015-123351A, which are not limited thereto.

The inner wall of the container is preferably formed of or coated with one or more resins selected from the group consisting of a polyethylene resin, a polypropylene resin, and a polyethylene-polypropylene resin, a resin different from these, and a metal such as stainless steel, HASTELLOY, INCONEL, or MONEL.

As the above-described different resin, a fluorine-based resin (a perfluororesin) can be preferably used. In this manner, by using a container in which an inner wall of the container is formed of a fluorine-based resin or coated with a fluororesin, the occurrence of a problem of elution of ethylene or propylene oligomers can be suppressed, as compared with a case of using a container in which an inner wall of the container is formed of or coated with a polyethylene resin, a polypropylene resin, or a polyethylene-polypropylene resin.

Specific examples of such a container having an inner wall include a FluoroPure PFA composite drum manufactured by Entegris Inc. In addition, it is also possible to use the containers described on page 4 of the pamphlet of JP1991-502677A (JP-H3-502677A), page 3 of the pamphlet of WO2004/016526A, and pages 9 and 16 of the WO99/46309A.

Further, for the inner wall of the container, quartz and an electropolished metal material (that is, a completely electropolished metal material) are also preferably used, in addition to the above-described fluorine-based resin.

The metal material that is used for producing the electropolished metal material is preferably a metal material which contains at least one selected from the group consisting of chromium and nickel, and it has a total content of chromium and nickel of more than 25% by mass with respect to the total mass of the metal material, and examples thereof include stainless steel and a nickel-chromium alloy.

The total content of chromium and nickel in the metal material is preferably 25% by mass or more and more preferably 30% by mass or more with respect to the total mass of the metal material.

It is noted that the upper limit value of the total content of Cr and Ni in the metal material is not particularly limited; however, it is generally preferably 90% by mass or less.

The stainless steel is not particularly limited, and known stainless steel can be used. Among them, an alloy containing nickel at 8% by mass or more is preferable, and austenitic stainless steel containing nickel at 8% by mass or more is more preferable. Examples of the austenitic stainless steels include SUS (Steel Use Stainless) 304 (Ni content: 8% by mass, Cr content: 18% by mass), SUS304L (Ni content: 9% by mass, Cr content: 18% by mass), SUS316 (Ni content: 10% by mass, Cr content: 16% by mass), and SUS316L (Ni content: 12% by mass, Cr content: 16% by mass).

The nickel-chromium alloy is not particularly limited, and known nickel-chromium alloys can be used. Among them, a nickel-chromium alloy having a nickel content of 40% to 75% by mass and a chromium content of 1% to 30% by mass is preferable.

Examples of the nickel-chromium alloy include HASTELLOY (product name, the same applies hereinafter), MONEL (product name, the same applies hereinafter), and INCONEL (product name, the same applies hereinafter). More specific examples thereof include HASTELLOY C-276 (Ni content: 63% by mass, Cr content: 16% by mass), HASTELLOY-C(Ni content: 60% by mass, Cr content: 17% by mass), and HASTELLOY C-22 (Ni content: 61% by mass, Cr content: 22% by mass).

In addition, the nickel-chromium alloy may further contain boron, silicon, tungsten, molybdenum, copper, cobalt, and the like as necessary, in addition to the above alloys.

A method of electropolishing a metal material is not particularly limited, and known methods can be used. For example, the methods described in paragraphs [0011] to [0014] of JP2015-227501A and paragraphs [0036] to [0042] of JP2008-264929A can be used.

In a case where the metal material is electropolished, it is presumed that a content of chromium in a passivation layer on a surface becomes larger than a content of chromium in a primary phase. As a result, it is presumed that since the metal element is unlikely to flow out into the composition from the inner wall coated with the electropolished metal material, the composition in which the specific metal element is reduced can be obtained.

The metal material is preferably subjected to buff polishing. A method of buff polishing is not particularly limited, and known methods can be used. The size of abrasive grains for polishing used for buff polishing finish is not particularly limited; however, it is preferably #400 or less from the viewpoint that then unevenness of the surface of the metal material is easily reduced.

The buff polishing is preferably carried out before the electropolishing.

In addition, the metal material may be treated by combining one or two or more of a plurality of stages of buff polishing, acid washing, magnetic fluid polishing, and the like, which are carried out by changing the count of the size or the like of the abrasive grains.

It is preferable to wash the inside of these containers before being filled. The liquid that is used for washing may be appropriately selected according to the intended use; however, it is preferably the composition, a liquid obtained by diluting the composition, or a liquid containing at least one of the components which are added to the composition.

In order to prevent the change in the components in the composition during storage, the inside of the container may be replaced with inert gas (nitrogen, argon, or the like) with a purity of 99.99995% by volume or more. In particular, a gas having a low moisture content is preferable. Although the liquid container body may be transported and stored at normal temperature, the temperature may be controlled in a range of −20° C. to 20° C. in order to prevent deterioration.

[Substrate Treatment Method]

In a substrate treatment method using the present composition (hereinafter, simply referred to as “the present treatment method”), the composition can be typically used by being brought into contact with a substrate containing a metal-based material which is a material containing a metal. At this time, the substrate may contain a plurality of kinds of metal-based materials. In addition, the composition may dissolve at least one of metal-based materials contained therein, where a plurality of kinds of the metal-based materials may be contained therein.

It suffices that the metal-based material has metal atoms (cobalt (Co), ruthenium (Ru), molybdenum (Mo), aluminum (Al), copper (Cu), titanium (Ti), tungsten (W), tantalum (Ta), and/or the like), and examples thereof include a single body metal, an alloy, a metal oxide (which may be a composite oxide), and a metal nitride (which may be a composite nitride). In addition, examples of the metal-based material contained in the substrate also include a material that contains at least one element selected from the group consisting of a single body metal, an alloy, a metal oxide, and a metal nitride, and at least one element, as a dopant, selected from the group consisting of carbon, nitrogen, boron, and phosphorus.

The content of the metal atom in the metal-based material is preferably 30% to 100% by mass, more preferably 40% to 100% by mass, and still more preferably 50% to 100% by mass, with respect to the total mass of the metal-based material.

In a case where the metal-based material contains the above dopant, the content of the dopant of the metal atom is preferably 0.1% to 50% by mass and more preferably 10% to 40% by mass with respect to the total mass of the metal-based material. In that case, the content of the metal atom in the metal-based material is preferably 30% to 99.9% by mass and more preferably 60% to 90% by mass with respect to the total mass of the metal-based material.

[Substrate Washing Method]

Examples of the present treatment method include a substrate washing method having a washing step B of washing a substrate including a metal layer using the above composition (hereinafter, also simply referred to as a “washing method”. The substrate washing method may include a composition production step A of preparing the composition, before the washing step B.

In the following description of the substrate washing method, a case where the composition production step A is carried out before the washing step B will be described as an example, which is not limited thereto, and the washing may be carried out using the composition prepared in advance.

[Object to Be Washed]

An object to be washed in the washing method is not particularly limited as long as it is a substrate including a metal layer, and a substrate including a metal layer containing at least Co or W is preferable. In addition, the object to be washed is preferably a substrate including a metal layer containing Cu, and it is also preferably a substrate including an SiOx layer in addition to the metal layer.

Examples of the object to be washed include a laminate in which at least a metal layer, an interlayer insulating film, and a metal hard mask are provided in this order on a substrate. The laminate may further have holes formed from the surface (the opening portion) of the metal hard mask toward the substrate so that the surface of the metal layer is exposed, as a result of undergoing a dry etching step or the like.

A method of manufacturing such a laminate having holes as described above is not particularly limited. However, in general, examples thereof include a method in which a laminate before treatment, having a substrate, a metal layer, an interlayer insulating film, and a metal hard mask in this order, is subjected to a dry etching step by using a metal hard mask as a mask and an interlayer insulating film is etched so that the surface of the metal layer is exposed, thereby providing holes that penetrate through the metal hard mask and the inside of the interlayer insulating film.

It is noted that a manufacturing method for the metal hard mask is not particularly limited. For example, first, a metal layer containing a predetermined component is formed on an interlayer insulating film, and a resist film having a predetermined pattern is formed on the metal layer. Next, a method of manufacturing a metal hard mask (that is, a film in which a metal layer is patterned) by etching a metal layer using a resist film as a mask can be mentioned.

In addition, the laminate may have a layer other than the above-described layer, and it may have, for example, a layer such as an etching stop film, a barrier layer, and/or an antireflection layer.

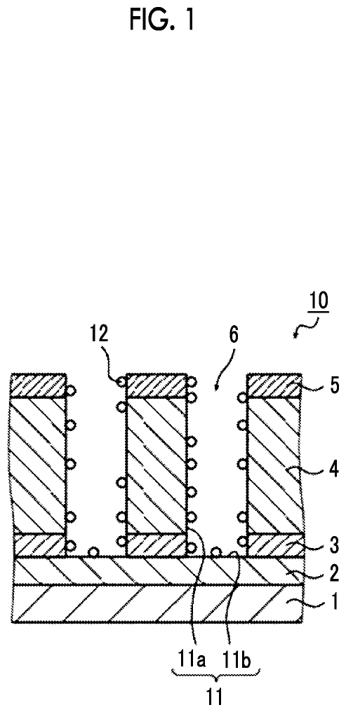

FIG. 1 shows a schematic cross-sectional view illustrating an example of a laminate which is an object to be washed in the substrate washing method.

A laminate 10 illustrated in FIG. 1 includes a metal layer 2, an etching stop layer 3, an interlayer insulating film 4, and a metal hard mask 5 in this order on a substrate 1, and holes 6 by which the metal layer 2 is exposed is formed at a predetermined position as a result of a dry etching step. That is, the object to be washed illustrated in FIG. 1 is a laminate which includes the substrate 1, the metal layer 2, the etching stop layer 3, the interlayer insulating film 4, and the metal hard mask 5 in this order, in which the holes 6 that penetrate from the surface of the metal hard mask 5 to the surface of the metal layer 2 at the position of the opening portion of the metal hard mask 5. An inner wall 11 of the holes 6 is composed of a cross-sectional wall 11a consisting of the etching stop layer 3, the interlayer insulating film 4, and the metal hard mask 5, and a bottom wall 11b consisting of the exposed metal layer 2, and dry etching residues 12 are attached to the inner wall 11.

The substrate washing method can be suitably used for the washing for the intended purpose of removing these dry etching residues 12. That is, while being excellent in the removal performance (the residue removability) for the dry etching residues 12, it is also excellent in the anticorrosion properties with respect to the inner wall 11 (for example, the metal layer 2 and the like) of the object to be washed.

In addition, a laminate that has undergone a dry ashing step after the dry etching step may be subjected to the substrate washing method.

Hereinafter, each layer-constituting material of the above-described laminate will be described.

<Metal Hard Mask>

The metal hard mask preferably contains at least one selected from the group consisting of copper, cobalt, a cobalt alloy, tungsten, a tungsten alloy, ruthenium, a ruthenium alloy, tantalum, a tantalum alloy, aluminum oxide, aluminum nitride, aluminum nitride oxide, titanium aluminum, titanium, titanium nitride, titanium oxide, zirconium oxide, hafnium oxide, tantalum oxide, lanthanum oxide, and a yttrium alloy (preferably YSiOx). Here, x and y are preferably numbers represented by x=1 to 3 and y=1 to 2, respectively.

Examples of the material of the metal hard mask include TiN, WO₂, and ZrO₂.

<Interlayer Insulating Film>

The material of the interlayer insulating film is not particularly limited, and examples thereof include those having a dielectric constant k of 3.0 or less and more preferably 2.6 or less.

Specific examples of the material of the interlayer insulating film include SiOx, SiN, SiOC, and an organic polymer such as polyimide. Here, x is preferably a number represented by 1 to 3.

<Etching Stop Layer>

The material of the etching stop layer is not particularly limited. Specific examples of the material of the etching stop layer include materials based on SiN, SiON, and SiOCN, and metal oxides such as AlOx. Here, x is preferably a number represented by 1 to 3.

<Metal Layer>

The material that forms the metal layer, which is a wiring line material and/or a plug material, is not particularly limited. However, it preferably contains one or more selected from the group consisting of cobalt, tungsten, molybdenum, and copper. Further, the material that forms the metal layer may be cobalt, tungsten, molybdenum, or an alloy of copper and another metal.

The metal layer may further contain a metal other than cobalt, tungsten, molybdenum, and copper, a metal nitride, and/or an alloy. Examples of the metal other than cobalt, tungsten, molybdenum, and copper, which may be contained in the metal layer include titanium, titanium-tungsten, titanium nitride, tantalum, a tantalum compound, chromium, a chromium oxide, and aluminum.

The metal layer may contain at least one dopant selected from the group consisting of carbon, nitrogen, boron, and phosphorus, in addition to one or more selected from the group consisting of cobalt, tungsten, molybdenum, and copper.

<Substrate>

The “substrate” referred to herein includes, for example, a semiconductor substrate consisting of a single layer and a semiconductor substrate consisting of multiple layers.

The material constituting a semiconductor substrate consisting of a single layer is not particularly limited, and, in general, it is preferably composed of a Group III-V compound, such as silicon, silicon germanium, or GaAs, or any combination thereof.

In a case of a semiconductor substrate consisting of multiple layers, the configuration thereof is not particularly limited, and it may have exposed integrated circuit structures such as interconnect structures (interconnect features) such as a metal wire and a dielectric material, for example, on the above-described semiconductor substrate such as silicon. Examples of the metal and the alloy which are used in the interconnect structure include aluminum, aluminum alloyed with copper, copper, titanium, tantalum, cobalt, silicon, titanium nitride, tantalum nitride, and tungsten, which are not limited thereto. In addition, a layer of an interlayer dielectric layer, silicon oxide, silicon nitride, silicon carbide, or silicon oxide doped with carbon may be provided on the semiconductor substrate.

(Barrier Layer)

The laminate may have a barrier layer. The barrier layer is a layer that is formed between a metal layer serving as a wiring line material and/or plug material provided on a substrate and an interlayer insulating film, and it is a layer (film) for preventing the diffusion of the wiring line material and/or the plug material.

Examples of the material of the barrier layer include a metal material having a low resistance, and the material thereof preferably includes at least one selected from the group consisting of tantalum or a tantalum compound, titanium or a titanium compound, tungsten or a tungsten compound, and ruthenium and more preferably includes at least one selected from the group consisting of TiN, TiW, Ta, TaN, W, WN, and Ru, and it is still more preferably TiN.

A manufacturing method for an object to be washed is not particularly limited as long as it is a method known in the field of the semiconductor substrate.

Examples of the method of forming a metal layer (a metal-containing film or a metal-containing wire) on a substrate include a sputtering method, a physical vapor deposition (PVD) method, an atomic layer deposition (ALD) method, a chemical vapor deposition (CVD) method, and a molecular beam epitaxy (MBE) method.

It is noted that in a case where a metal-containing film is formed according to a sputtering method, a PVD method, an ALD method, a CVD method, or the like, a metal-containing substance may also adhere to the back surface of the substrate having the metal-containing film (the surface opposite to the side of the metal-containing film).

In addition, a metal-containing wire may be formed on a substrate by carrying out the above-described method through a predetermined mask.

In addition, after forming the metal layer on the substrate, this substrate may be subjected to a different step or a different treatment and then used as an object to be treated in the present treatment method.

For example, a substrate having a metal layer may be subjected to dry etching to manufacture a substrate having a dry etching residue containing a metal. The dry etching residue is a by-product generated by carrying out dry etching (for example, plasma etching), and examples thereof include an organic residue derived from a photoresist, an Si-containing residue derived from an interlayer insulating film, and a metal-containing residue. In addition, a substrate having a metal layer may be subjected to CMP to manufacture a substrate having a metal-containing substance.

Hereinafter, the substrate washing method will be described for each step.

[Composition Production Step A]

The composition production step A is a step of preparing the composition. Each component that is used in this step is as described above. In addition, the details of this step are as described in the column of [Production method for composition] described above.

The procedure of this step is not particularly limited, and examples thereof include a method of preparing a composition by stirring and mixing predetermined components. It is noted that each component may be added at one time or may be dividedly added over a plurality of times.

In addition, as each component contained in the composition, a component classified into a semiconductor grade or a component classified into a high-purity grade equivalent thereto is used, and it is preferable to use a component in which foreign matters are removed by filtering and/or ion components are reduced by an ion exchange resin or the like. In addition, after mixing the raw material components, it is preferable to carry out the removal of foreign matters by filtering and/or the reduction of ion components by an ion exchange resin or the like.

Further, in a case where the composition is a concentrated solution, the concentrated solution is diluted 5 to 2,000 times to obtain a diluent liquid before carrying out the washing step B, and then the washing step B is carried out using this diluent liquid. The solvent for diluting a concentrated solution is preferably at least one selected from the group consisting of water, alcohol, and an aprotic polar solvent, which are contained in the composition.

[Washing Step B]

Examples of the object to be washed in the washing step B include the above-described laminate, and more specific examples thereof include a substrate including a metal layer that contains at least one metal selected from the group consisting of Co and W. In addition, examples of the object to be washed include a laminate 10 that has undergone a dry etching step to form holes, as described above (see FIG. 1). It is noted that the dry etching residues 12 adhere to the holes 6 in the laminate 10. In addition, a laminate that has undergone a dry ashing step after the dry etching step may be used as the object to be washed.

A method of bringing the composition into contact with an object to be washed is not particularly limited. However, examples thereof include a method of immersing an object to be washed, in the composition charged in a container such as a tank, a method of spraying the composition onto an object to be washed, a method of allowing the composition to flow onto an object to be washed, and any combination thereof. From the viewpoint of residue removability, a method of immersing an object to be washed, in the composition, is preferable.

The temperature of the composition is preferably 90° C. or less, more preferably 25° C. to 80° C., still more preferably 30° C. to 75° C., and particularly preferably 40° C. to 65° C.

The washing time can be adjusted according to the washing method to be used and the temperature of the composition to be used.

In a case of carrying out washing by an immersion batch method (a batch method in which a plurality of objects to be washed are immersed and treated in a treatment tank), the washing time is, for example, within 90 minutes, and it is preferably 10 to 90 minutes, more preferably 5 to 60 minutes, and still more preferably 10 to 45 minutes.

In a case of carrying out washing by the single substrate method, the washing time is, for example, 10 seconds to 5 minutes, and it is preferably 15 seconds to 4 minutes, more preferably 15 seconds to 3 minutes, and still more preferably 20 seconds to 2 minutes.

Further, in order to further improve the washing ability of the composition, a mechanical stirring method may be used.

Examples of the mechanical stirring method include a method of circulating a composition on an object to be washed, a method of flowing or spraying a composition on an object to be washed, and a method of stirring a composition with an ultrasonic wave or a megasonic wave.

[Rinsing Step B2]

The substrate washing method according to the embodiment of the present invention may further include a step of rinsing the object to be washed with a solvent (hereinafter, referred to as a “rinsing step B2”), after the washing step B.

The rinsing step B2 is carried out continuously after the washing step B, and it is preferably a step of carrying out rising with a rinsing solvent (a rinsing liquid) for 5 seconds to 5 minutes. The rinsing step B2 may be carried out using the above-described mechanical stirring method.

Examples of the solvent of the rinsing liquid include deionized water (DIW), methanol, ethanol, isopropanol, N-methylpyrrolidinone, γ-butyrolactone, dimethyl sulfoxide, ethyl lactate, and propylene glycol monomethyl ether acetate.

The solvent of the rinsing liquid is preferably DIW, methanol, ethanol, isopropanol, or a mixed liquid thereof, and more preferably DIW, isopropanol, or a mixed liquid of DIW and isopropanol.

As a method of bringing the rinsing solvent into contact with the object to be washed, the above-described method of bringing the above-described composition into contact with the object to be washed can be similarly applied.

The temperature of the rinsing solvent in the rinsing step B2 is preferably 10° C. to 40° C.

[Drying Step B3]

The substrate washing method according to the embodiment of the present invention may include a drying step B3 of drying the object to be washed, after the rinsing step B2.

The drying method is not particularly limited. Examples of the drying method include a spin drying method, a method of flowing a dry gas onto an object to be washed, a method of heating a substrate by a heating means such as a hot plate and an infrared lamp, a Marangoni drying method, a Rotagoni drying method, an isopropanol (IPA) drying method, and any combinations thereof.

The drying time in the drying step B3 depends on the specific drying method; however, it is preferably 20 seconds to 5 minutes.

The heating temperature in a case where a substrate is dried by heating is not particularly limited; however, it is, for example, 50° C. to 350° C. and preferably 150° C. to 250° C.

[Coarse Particle Removal Step H]

After the composition production step A and before the washing step B, the substrate washing method preferably has a coarse particle removal step H of removing coarse particles in the composition.

In a case of reducing or removing the coarse particles in the composition, it is possible to reduce the amount of the coarse particles remaining on the object to be washed after undergoing the washing step B. As a result, it is possible to suppress the pattern damage caused by the coarse particles on the object to be washed, and it is also possible to suppress the influence on the decrease in the yield and the decrease in the reliability of the device.

Examples of the specific method for removing the coarse particles include a method of filtering and purifying the composition that has undergone the composition production step A, by using a particle removal film having a predetermined particle removal diameter.

It is noted that the definition of the coarse particle is as described above.

[Destaticization Steps I and J]

It is preferable that the substrate washing method include at least one step selected from the group consisting of a destaticization step I of destaticizing the water that is used in the preparation of a composition before the composition production step A and a destaticization step J of destaticizing the composition after the composition production step A and before the washing step B.

It is preferable that a material of a liquid contact portion for supplying the composition to the object to be washed is formed of or coated with a material in which metal elution due to the composition does not occur. Examples of the above-described material include the material already described as the material involved in the inner wall of the container that can be used in the liquid container body.

The above-described material may be a resin. In a case where the above-described material is a resin, the resin has a low electrical conductivity and insulating properties in a large number of cases. As a result, for example, in a case where the composition is allowed to pass through a pipe of which the inner wall is formed of or coated with a resin, or in a case where it is subjected to filtration and purification with a particle removal film made of a resin and an ion exchange resin film made of a resin, the charged potential of the composition may increase, which causes an electrostatic disaster.

Therefore, in the substrate washing method according to the embodiment of the present invention, it is preferable to carry out at least one of the destaticization step I or the destaticization step J described above to reduce the charged potential of the composition. In addition, in a case of carrying out destaticization, it is possible to further suppress the adhesion of foreign matters (coarse particles or the like) to the substrate and/or the damage (the corrosion) to the object to be washed.

Specific examples of the destaticization method include a method of bringing water and/or the composition into contact with a conductive material.

The contact time during which the water and/or the composition is brought into contact with a conductive material is preferably 0.001 to 1 second and more preferably 0.01 to 0.1 second.

Examples of the resin include high-density polyethylene (HDPE), high-density polypropylene (PP), 6,6-nylon, tetrafluoroethylene (PTFE), a copolymer (PFA) of tetrafluoroethylene and perfluoroalkyl vinyl ether, polychlorotrifluoroethylene (PCTFE), an ethylene-chlorotrifluoroethylene copolymer (ECTFE), an ethylene-ethylene tetrafluoride copolymer (ETFE), and an ethylene tetrafluoride-propylene hexafluoride copolymer (FEP).

Examples of the conductive material include stainless steel, gold, platinum, diamond, and glassy carbon.

The substrate washing method may be a substrate washing method that has the composition production step A, the washing step B, a waste liquid recovery step C of recovering a waste liquid of the composition used in the washing step B, a washing step D of washing a substrate including a newly prepared and predetermined layer by using the recovered waste liquid of the composition, and a waste liquid recovery step E of recovering the waste liquid of the composition, used in the washing step D, where the washing step D and the waste liquid recovery step E are repeatedly carried out to recycle the waste liquid of the composition.

In the above-described substrate washing method, the aspects of the composition production step A and the washing step B are as described above. In addition, it is preferable that the aspect of reusing the waste liquid also has the above-described coarse particle removal step H and the above-described destaticization steps I and J.

The aspect of the washing step D of carrying out the washing of the substrate using the waste liquid of the recovered composition is as described regarding the washing step B.

The waste liquid recovery means in the waste liquid recovery steps C and E is not particularly limited. The recovered waste liquid is preferably stored in the above-described container in the destaticization step J, and at the time of the storage, the same destaticization step as in the destaticization step J may be carried out. In addition, a step of removing impurities by subjecting the recovered waste liquid to filtration or the like may be provided.

### EXAMPLES

Hereinbelow, the present invention will be described in more detail with reference to Examples. The materials, amounts of use, proportions, treatments, procedures, and the like described in the following Examples can be appropriately modified as long as the gist of the invention is maintained. Therefore, the scope of the present invention should not be construed to be limited by Examples described below.

### Examples 1 to 30 and Comparative Example 1

[Preparation of Composition]

Each of components shown in Table 1 was prepared and then added and mixed according to the formulation ratio shown in Table 1 to prepare each of compositions of Examples and Comparative Examples. It is noted that in each composition, the content of each component (all in terms of mass) is as described in the table.

Here, as the components shown in Table 1, those all classified into a semiconductor grade or a high-purity grade equivalent thereto were used.

<Component>

The various components listed in Table 1 are shown below.

(Alcohol)
t-butanol
1-butanol
2-butanol
Cyclopentanol
Ethanol
2-propanol (IPA)
Diethylene glycol monobutyl ether (DEGBE)
Tetrahydrofurfuryl alcohol (THFA)

(Aprotic Polar Solvent (described as “Specific solvent” in the table))
Dimethyl sulfoxide (DMSO)
Sulfolane

(Azole Compound)
1,2,4-triazole
1H-benzotriazole
Tolyltriazole

(Alkanolamine)
2-Aminoethanol
Diethanolamine
2-(2-aminoethoxy)ethanol (AEE)

(Water)
Deionized water (DIW)

(Component A)
Dipropyl sulfone
2-sulfolene

[Evaluation]

[Residue Removability]

A laminate, in which a SiO₂ film having a thickness of 100 nm, a metal hard mask (TiN), and a resist film were laminated in this order on a substrate (Si), was prepared. This laminate was subjected to a patterning treatment by lithography, a dry etching treatment using a plasma etching apparatus for metal, and a removal treatment of a resist film by oxygen plasma ashing, thereby producing a laminate for an evaluation test, in which a predetermined opening portion was formed in the metal hard mask.

Using the obtained laminate, plasma etching was carried out with a gas containing fluorine using a metal hard mask as a mask, to subject the SiO₂ film to etching of about 50 nm, thereby producing a test piece for an evaluation test, in which a lattice form pattern of the 2 cm square was formed. As a result of analyzing the etched bottom surface by X-ray photoelectron spectroscopy (XPS), the fluorine presumed to be derived from the dry etching residue was detected. It is presumed that the dry etching residue formed by plasma etching using the above-described gas containing fluorine is an organic/inorganic mixed residue encompassing Si and O derived from SiO₂ and C and F derived from the etching gas.

Next, the residue removability of each composition was evaluated according to the following procedure.

A glass beaker having a volume of 500 mL was filled with 200 mL of the composition. The temperature of the composition was raised to 40° C. while carrying out stirring using a stirrer. Next, the test piece prepared as described above was immersed, while carrying out stirring, in the composition having a liquid temperature of 40° C. for 2 minutes, whereby the test piece was washed. While the test piece was immersed in the composition, the test piece was held using plastic locking tweezers having a length of 4 inches so that the surface of the test piece, from which the residue had been removed, faced the stirrer.

After the washing time elapsed, the test piece was immediately taken out from the composition and placed in a 500 mL plastic beaker filled with 400 mL of DI water (water temperature: 20° C.) in a state of being gently stirred. During the immersion of the test piece in DI water, the test piece was held using plastic locking tweezers having a length of 4 inches so that the surface of the test piece, from which the residue had been removed, faced the stirrer.

After the test piece was immersed in DI water for 30 seconds, the test piece was immediately taken out and rinsed under a DI water flow at 20° C. for 30 seconds. During the rinsing of the test piece under the DI water stream, the test piece was held using a plastic locking tweezers having a length of 4 inches so that the surface of the test piece, from which the residue had been removed, faced the DI water stream.

Subsequently, the test piece was exposed to a stream of nitrogen gas to blow off liquid droplets that had adhered to the surface of the test piece, whereby the surface of the test piece was dried.

After this nitrogen drying step, the test piece was removed from the holding portion of the plastic tweezers, and the test piece was placed and stored in a plastic storage box attached with a lid, with the element side facing up.

The composition of the surface of the obtained test piece was analyzed by XPS. The surface of the test piece was measured using an XPS apparatus (manufactured by ULVAC-PHI, Inc., trade name: Quantera SXM), and the residue removability (the removability of the dry etching residues) was evaluated from the measurement results of the content (% by atom) of the fluorine atom derived from the dry etching residue on the surface of the test piece. It can be said that a case where the amount of the fluorine atom on the surface of the test piece is small is excellent in residue removability, and a case where the amount of the fluorine atom is large is inferior in residue removability.

(Evaluation Standard for Residue Removability)

A: The content of the fluorine atom on the surface of the test piece is less than 1% by atom.

B: The content of the fluorine atom on the surface of the test piece is 1% by atom or more and less than 1.5% by atom.

C: The content of the fluorine atom on the surface of the test piece is 1.5% by atom or more and less than 2.5% by atom.

D: The content of the fluorine atom on the surface of the test piece is 2.5% by atom or more.

[Anticorrosion Properties]

A substrate on which a film (Co film) consisting of cobalt was formed according to a chemical vapor deposition (CVD) method was prepared on one surface of a commercially available silicon wafer (diameter: 12 inches). The thickness of the formed Co film was 30 nm.

The obtained Co film was subjected to an etching treatment using each of the compositions of Examples and Comparative Examples. Specifically, after immersing the Co film in each of the compositions of Examples and Comparative Examples for 10 minutes, a rinsing treatment of carrying out rinsing in pure water for 15 seconds was carried out twice, and subsequently, the substrate was dried with nitrogen gas. The etching rate (A/min) was calculated based on the difference in film thickness of the Co film before and after the immersion in the composition.

The anticorrosion properties of the composition were evaluated from the measured etching rate of each film. It can be said that a case where the etching rate is low is excellent in anticorrosion properties, and a case where the etching rate is high is inferior in anticorrosion properties.

In the same manner as described above, a substrate having each of a film consisting of W (a W film), a film consisting of TiN (a TiN film), a film consisting of AlOx (an AlOx film), and a film consisting of Mo (an Mo film) was prepared, and each substrate was immersed in each composition, and the etching rate (A/min) of each film was measured.

It is noted that the W film, the TiN film, and the AlOx film were formed according to a CVD method, and the Mo film was formed according to a physical vapor deposition (PVD) method.

It is noted that the thickness of each film formed on the substrate was measured according to the following method.

The thicknesses of the Co film, the W film, and the TiN film were measured according to an X-ray fluorescence analysis method (X-ray fluorescence method: XRF) using a fluorescence X-ray analysis apparatus (“AZX400” manufactured by Rigaku Corporation).

The thickness of the AlOx film was measured using ellipsometry (spectral ellipsometer: trade name “Vase”, manufactured by J.A. Woollam Japan Corp.) under the conditions of a measurement range of 250 to 1,000 nm and a measurement angle of 70 degrees and 75 degrees.

The thickness of the Mo film was measured according to a 4-terminal method using a specific resistance measuring device (“VR300DE” manufactured by Kokusai Electric Semiconductor Service Inc.).

Table 1 summarizes the measurement results.

[Defect Suppressibility]

The number of particles having a diameter of 19 nm or more and the addresses of the respective particles present on the surface of a silicon substrate (wafer) having a diameter of 300 mm were measured with a wafer surface examination apparatus (SP-5, manufactured by KLA-Tencor Corporation).

Then, the wafer in which the number of particles present on the surface of the silicon substrate was measured was set in a spin rotary wafer processing apparatus (manufactured by EKC technologies Inc.).

Next, each of the compositions of Examples and Comparative Examples, which had been adjusted to 40° C., was discharged onto the surface of the set wafer at a flow rate of 1.5 L/min for 1 minute. Then, water was discharged onto the surface of the wafer at a flow rate of 1 L/min for 1 minute to spin-dry the wafer.

Regarding the obtained dried wafer, the number of particles having a diameter of 19 nm or more and the address on the wafer were measured using the wafer surface examination apparatus, and the increased number of particles having a diameter of 19 nm or more, before and after washing using each composition, as measured. Table 1 shows the measurement results of the increased number of particles having a diameter of 19 nm or more.

The following Table 1 shows the composition of the used composition and the evaluation results in each Example and each Comparative Example.

In the table, the column of “Ratio 1” indicates the ratio of the content of the azole compound to the content of the component A in each composition (azole compound/component A) in terms of mass ratio, and the column of “Ratio 2” indicates the ratio of the content of the aprotic polar solvent to the content of the component A in each composition (aprotic polar solvent/component A) in terms of mass ratio. For example, the notation of “5.0E+04” in the column of “Ratio 1” of Example 8 indicates that the ratio 1 (azole compound/component A) is “5.0×10⁴ in terms of mass ratio.

The column of “pH” indicates the pH of each composition measured using a pH meter at 25° C.

TABLE 1

| | | | Example 1 | Example 2 | Example 3 | Example 4 | Example 5 | Example 6 |
|---|---|---|---|---|---|---|---|---|
| Composition | Alcohol | t-butanol | 65.0 | 60.0 | | 52.0 | 60.0 | 49.0 |
| | | 1-butanol | | | | | | |
| | | 2-butanol | | | | | | |
| | | Cycolpentanol | | | 65.0 | | | |
| | | Ethanol | | | | | | |
| | | IPA | | | | | | |
| | | DEGBE | | | | | | |
| | | THFA | | | | | | |
| | Specific | DMSO | | | | | | |
| | solvent | Sulfolane | 10.0 | 10.0 | 10.0 | 18.0 | 10.0 | 10.0 |
| | Azole | 1,2,4-triazole | 1.0 | 1.0 | 1.0 | 3.0 | 0.2 | 3.0 |
| | compound | 1H-benzotriazole | | | | | | |
| | | Tolyltriazole | | | | | | |
| | Alkanolamine | 2-aminoethanol | 1.0 | 2.6 | 3.0 | 6.2 | 0.2 | 6.2 |
| | | Diethanolamine | | | | | | |
| | | AEE | | | | | | |
| | DIW | | 23.0 | 26.4 | 21.0 | 20.8 | 29.6 | 31.8 |
| | Component A | Dipropyl sulfone | | | | | | |
| | | 2-sulfolene | | | | | | |
| | Ratio 1 | | | | | | | |
| | Ratio 2 | | | | | | | |
| | pH | | 10.25 | 10.50 | 10.60 | 10.50 | 9.20 | 10.50 |
| Evaluation | Residue removability | | A | A | A | A | A | A |
| | Anticorrosion | Co | 0.6 | 0.6 | 0.8 | 1.5 | 2.2 | 1.5 |
| | properties | W | 3.4 | 4.2 | 4.9 | 4.5 | 2.2 | 5.3 |
| | (Å/min) | TiN | 0.4 | 0.2 | 0.2 | 0.2 | 0.2 | 0.2 |
| | | AlOx | 1.4 | 2.4 | 2.4 | 1.8 | 0.6 | 1.8 |
| | | Mo | 137.2 | 158.0 | 161.0 | 113.2 | N.D. | 113.2 |

| | | | | | | |
|---|---|---|---|---|---|---|
| Defect suppressibility | 301 | 251 | 298 | 401 | 332 | 318 |

| | | | Example 7 | Example 8 | Example 9 | Example 10 |
|---|---|---|---|---|---|---|
| Composition | Alcohol | t-butanol | | 67.0 | 65.0 | |
| | | 1-butanol | | | | |
| | | 2-butanol | | | | |
| | | Cycolpentanol | | | | |
| | | Ethanol | | | | 65.0 |
| | | IPA | 65.0 | | | |
| | | DEGBE | | | | |
| | | THFA | | | | |
| | Specific | DMSO | | | | |
| | solvent | Sulfolane | 1.0 | 10.0 | 10.0 | 10.0 |
| | Azole | 1,2,4-triazole | 1.0 | 5.0 | 6.0 | 1.0 |
| | compound | 1H-benzotriazole | | | | |
| | | Tolyltriazole | | | | |
| | Alkanolamine | 2-aminoethanol | 1.5 | 6.2 | 6.2 | 1.7 |
| | | Diethanolamine | | | | |
| | | AEE | | | | |

| DIW | | 31.5 | 11.8 | 12.8 | 22.3 |
|---|---|---|---|---|---|
| Component A | Dipropyl sulfone | | | | |
| | 2-sulfolene | | 100 ppm | 300 ppm | |

| | | | | | |
|---|---|---|---|---|---|
| | Ratio 1 | | 5.0E+04 | 2.0E+04 | |
| | Ratio 2 | | 1.0E+05 | 3.3E+04 | |
| | pH | 10.30 | 10.50 | 10.50 | 10.40 |
| Evaluation | Residue removability | A | A | A | A |

| | | | | | |
|---|---|---|---|---|---|
| Anticorrosion | Co | 0.6 | 1.5 | 0.3 | 0.5 |
| properties | W | 4.8 | 4.5 | 4.4 | 4.8 |
| (Å/min) | TiN | 0.2 | 0.2 | 0.2 | 0.2 |
| | AlOx | 2.0 | 1.8 | 1.8 | 2.0 |
| | Mo | N.D. | N.D. | N.D. | N.D. |

| | | | | |
|---|---|---|---|---|
| Defect suppressibility | 265 | 139 | 1511 | 298 |

TABLE 2

| | | | Example 11 | Example 12 | Example 13 | Example 14 | Example 15 |
|---|---|---|---|---|---|---|---|
| Composition | Alcohol | t-butanol | 65.0 | 60.0 | 78.0 | 60.0 | 65.0 |
| | | 1-butanol | 30.0 | | | | |
| | | 2-butanol | | | | | |
| | | Cycolpentanol | | | | | |
| | | Ethanol | | | | | |
| | | IPA | | | | | |
| | | DEGBE | | | | | |
| | | THFA | | | | | |
| | Specific | DMSO | | 10.0 | | | |
| | solvent | Sulfolane | 10.0 | | 10.0 | 0.5 | 10.0 |
| | Azole | 1,2,4-triazole | 1.0 | 0.2 | | | 1.0 |
| | compound | 1H-benzotriazole | | | 0.1 | 0.3 | |
| | | Tolyltriazole | | | | | |
| | Alkanolamine | 2-aminoethanol | 2.6 | 0.5 | | 2.0 | 2.6 |
| | | Diethanolamine | | | 1.9 | | |
| | | AEE | | | | | |
| | DIW | | 21.4 | 29.3 | 10.0 | 37.2 | 21.4 |
| | Component A | Dipropyl sulfone | | | | | |
| | | 2-sulfolene | 10 ppm | | 10 ppm | | 10 ppt |
| | Ratio 1 | | 1.0E+05 | | 1.0E+04 | | 1.0E+11 |
| | Ratio 2 | | 1.0E+06 | | 1.0E+06 | | 1.0E+12 |
| | pH | | 10.5 [symbol] | 9.50 | 10.50 | 10.30 | 10.50 |
| Evaluation | Residue removability | | A | A | A | A | A |
| | Anticorrosion | Co | 0.6 | 1.5 | 2.3 | 0.3 | 2.7 |
| | properties | W | 4.2 | 3.0 | 4.1 | 8.0 | 4.2 |
| | (Å/min) | TiN | 0.2 | 0.3 | 0.1 | 0.2 | 0.2 |
| | | AlOx | 2.4 | 1.0 | N.D. | 6.2 | 2.4 |
| | | Mo | N.D. | N.D. | N.D. | N.D. | N.D. |
| | Defect suppressibility | | 101 | 299 | 156 | 301 | 189 |
| | | | Example 16 | Example 17 | Example 18 | Example 19 | Example 20 |
| Composition | Alcohol | t-butanol | 65.0 | 60.0 | 60.0 | 60.0 | |
| | | 1-butanol | | | | | 55.0 |
| | | 2-butanol | | | | | |
| | | Cycolpentanol | | | | | |
| | | Ethanol | | | | | |
| | | IPA | | | | | |
| | | DEGBE | | | | | |
| | | THFA | | | | | |
| | Specific | DMSO | | 10.0 | 10.0 | 10.0 | |
| | solvent | Sulfolane | 10.0 | | | | 10.0 |
| | Azole | 1,2,4-triazole | 3.0 | 0.2 | 0.2 | 0.2 | 1.0 |
| | compound | 1H-benzotriazole | | | | | |
| | | Tolyltriazole | | | | | |
| | Alkanolamine | 2-aminoethanol | 6.2 | 1.0 | 9.0 | 9.0 | |
| | | Diethanolamine | | | | | 2.0 |
| | | AEE | | | | | |
| | DIW | | 15.8 | 28.8 | 20.8 | 20.8 | 32.0 |
| | Component A | Dipropyl sulfone | | | | | |
| | | 2-sulfolene | 1000 ppm | | 100 ppt | | |
| | Ratio 1 | | 3.0E+03 | | 2.0E+09 | | |
| | Ratio 2 | | 1.0E+04 | | 1.0E+11 | | |
| | pH | | 10.50 | 10.00 | 10.90 | 10.90 | 10.40 |
| Evaluation | Residue removability | | A | A | A | A | A |
| | Anticorrosion | Co | 1.3 | 1.5 | 0.7 | 0.7 | 0.6 |
| | properties | W | 4.1 | 6.0 | 8.0 | 7.0 | 3.8 |
| | (Å/min) | TiN | 0.2 | 0.3 | 0.3 | 0.3 | 0.3 |
| | | AlOx | 1.8 | 1.8 | 4.0 | 4.5 | 1.9 |
| | | Mo | N.D. | N.D. | N.D. | N.D. | N.D. |

| | | | | | |
|---|---|---|---|---|---|
| Defect suppressibility | 1060 | 287 | 201 | 366 | 319 |

[symbol]

indicates data missing or illegible when filed

TABLE 3

| | | | Example 21 | Example 22 | Example 23 | Example 24 | Example 25 | Example 26 |
|---|---|---|---|---|---|---|---|---|
| Composition | Alcohol | t-butanol | 41.0 | | | 60.0 | | 60.0 |
| | | 1-butanol | | | 60.0 | | 60.0 | |
| | | 2-butanol | | 40.0 | | | | |
| | | Cycolpentanol | | | | | | |
| | | Ethanol | | | | | | |
| | | IPA | | | | | | |
| | | DEGBE | | | | | | |
| | | THFA | | | | | | |
| | Specific | DMSO | | | | | | 15.0 |
| | solvent | Sulfolane | 10.0 | 10.0 | 11.0 | 10.0 | 10.0 | |
| | Azole | 1,2,4-triazole | 3.0 | 1.0 | | | | 3.0 |
| | compound | 1H-benzotriazole | | | 0.5 | 0.1 | | |
| | | Tolyltriazole | | | | | 0.2 | |
| | Alkanolamine | 2-aminoethanol | | | | | | 1.0 |
| | | Diethanolamine | 8.1 | | 1.9 | 1.9 | | |
| | | AEE | | 2.0 | | | 2.5 | |
| | DIW | | 37.9 | 47.0 | 26.6 | 28.0 | 27.3 | 21.0 |
| | Component A | Dipropyl sulfone | | | | | | 10 ppm |
| | | 2-sulfolene | | | 10 ppb | 10 ppm | | |
| | Ratio 1 | | | | 5.0E+04 | 1.0E+04 | | 1.0E+05 |
| | Ratio 2 | | | | 1.1E+09 | 1.0E+06 | | 1.5E+06 |
| | pH | | 10.70 | 10.40 | 10.50 | 10.50 | 10.30 | 10.00 |
| Evaluation | Residue removability | | A | A | A | A | A | A |
| | Anticorrosion | Co | 1.5 | 2.7 | 0.6 | 0.6 | 0.4 | 0. [symbol] |
| | properties | W | 4.1 | 6.0 | 4.1 | 4.1 | 3.4 | 5.0 |
| | (Å/min) | TiN | 0.4 | 0.2 | 0.3 | 0.3 | 0.4 | 0.3 |
| | | AlOx | 2.1 | N.D. | N.D. | N.D. | N.D. | 1.8 |
| | | Mo | N.D. | N.D. | N.D. | N.D. | N.D. | N.D. |

| | | | | | | |
|---|---|---|---|---|---|---|
| Defect suppressibility | 309 | 401 | 105 | 1 [symbol] 7 | 341 | 1 [symbol] |

| | | | | | | | Comparative |
|---|---|---|---|---|---|---|---|
| | | | Example 27 | Example 28 | Example 29 | Example 30 | Example 1 |
| Composition | Alcohol | t-butanol | | | 52.0 | 35.0 | 75.0 |
| | | 1-butanol | | | | | |
| | | 2-butanol | | | | | |
| | | Cycolpentanol | | | | | |
| | | Ethanol | | | | | |
| | | IPA | | | | | |
| | | DEGBE | | 50.0 | | | |
| | | THFA | 30.0 | | | | |
| | Specific | DMSO | | | | | |
| | solvent | Sulfolane | 10.0 | 10.0 | 18.0 | 10.0 | |
| | Azole | 1,2,4-triazole | 1.0 | | 3.0 | | 1.0 |
| | compound | 1H-benzotriazole | | 0.3 | | 0.3 | |
| | | Tolyltriazole | | | | | |
| | Alkanolamine | 2-aminoethanol | 1.0 | 1.0 | 0.2 | 12.0 | 1.0 |
| | | Diethanolamine | | | | | |
| | | AEE | | | | | |

| DIW | | 38.0 | 26.8 | 42.7 | 23.0 |
|---|---|---|---|---|---|
| Component A | Dipropyl sulfone | | | | |
| | 2-sulfolene | | | | |

| | | | | | | |
|---|---|---|---|---|---|---|
| | Ratio 1 | | | | | |
| | Ratio 2 | | | | | |
| | pH | 10.10 | 10.30 | 8.50 | 11.30 | 10.25 |
| Evaluation | Residue removability | B | B | A | A | D |

| | | | | | | |
|---|---|---|---|---|---|---|
| Anticorrosion | Co | 3.1 | 1.2 | 7.0 | 0.3 | 5.0 |
| properties | W | 5.5 | 4.1 | 2.5 | 11.0 | 3.4 |
| (Å/min) | TiN | 0.2 | 0.2 | 0.2 | 0.2 | 0.4 |
| | AlOx | 2.1 | 2.3 | 0.8 | 6.2 | 1.4 |
| | Mo | N.D. | N.D. | 89.0 | N.D. | 117.2 |

| | | | | | |
|---|---|---|---|---|---|
| Defect suppressibility | 405 | 112 | 368 | 38 [symbol] | 387 |

[symbol]

indicates data missing or illegible when filed

From the results shown in Table 1, it has been confirmed that the present composition is more excellent in the effect of the present invention as compared with the compositions of Comparative Examples.

It has been confirmed that in a case where the main chain skeleton of the alcohol is a main chain skeleton consisting of an aliphatic hydrocarbon group or does not have a cyclic structure, the residue removability and the Co anticorrosion properties are more excellent (the comparison among Examples 1 to 28).

It has been confirmed that in a case where the pH is 9 to 11, the Co anticorrosion properties and the W anticorrosion properties are more excellent (the comparison among Examples 1 to 30).

### Examples 31 to 41

[Preparation of Composition]

t-butanol, sulfolane, 1,2,4-triazole, 2-aminoethanol, deionized water, and a chelating agent shown in Table 2 described below, were prepared, and these components were mixed to prepare each of compositions of Examples 31 to 41.

The contents of the t-butanol, sulfolane, 1,2,4-triazole, and deionized water contained in each of the compositions of Examples 31 to 41 were the same as the contents of the respective components contained in the composition of Example 2, described in Table 1. The content of 2-aminoethanol was adjusted so that the pH of each of the compositions of Examples 31 to 41 were the numerical value described in the column of “pH” of Table 2. In addition, Table 2 shows the kinds and contents of the chelating agent contained in each of the compositions.

The chelating agents used in the preparation of the compositions of Examples 31 to 41 are shown below. As the chelating agent, a compound classified into a semiconductor grade or a compound classified into a high-purity grade equivalent thereto was used.

(Chelating Agent)
CA1: Ethylenediaminetetraacetic acid
CA2: Diethylenetriaminepentaacetic acid
CA3: Citric acid
CA4: N,N,N′,N′-ethylenediaminetetrakis(methylenephosphonic acid)
CA5: Gluconic acid
CA6: Malonic acid
CA7: Iminodiacetic acid

[Evaluation]

Residue removability, anticorrosion properties, and defect suppressibility were evaluated regarding the compositions of Examples 31 to 41 and the composition of Example 2 for reference.

The evaluation of the residue removability was carried out according to the same method as the evaluation method for the residue removability with respect to the compositions of Examples 1 to 30, including the production, procedure, analysis method, and evaluation standards of the test piece as well, except that the time taken for immersing the prepared test piece in each of the compositions at a liquid temperature of 40° C. was changed from 2 minutes to 1 minute.

In addition, regarding the evaluation of the anticorrosion properties and the defect suppressibility, the evaluation was carried out according to the same method as the evaluation method for the compositions of Examples 1 to 30.

Table 2 shows the evaluation results of the composition of each Example.

The meanings of the columns other than the column of “Chelating agent” in Table 2 are the same as those in Table 1.

TABLE 4

| | | | Example 2 | Example 31 | Example 32 | Example 33 | Example 34 | Example 35 | Example 36 |
|---|---|---|---|---|---|---|---|---|---|
| Composition | Chelating | CA1 | | 0.1 | | | | | |
| | agent | CA2 | | | 0.1 | | | | |
| | | CA3 | | | | 0.1 | | | |
| | | CA4 | | | | | 0.1 | | |
| | | CA5 | | | | | | 0.1 | |
| | | CA6 | | | | | | | 0.1 |
| | | CA7 | | | | | | | |
| | pH | | 10.50 | 10.50 | 10.50 | 10.50 | 10.50 | 10.50 | 10.50 |
| | Residue removability | | B | A | A | A | A | A | A |
| Evaluation | Anticorrosion | Co | 0.6 | 0.4 | 0.3 | 0.6 | 0.4 | 0.3 | 0.4 |
| | properties | W | 4.2 | 4.1 | 3.8 | 3.0 | 3.2 | 3.4 | 4.9 |
| | (Å/min) | TiN | 0.2 | 0.4 | 0.5 | 0.3 | 0.3 | 0.2 | 0.3 |
| | | AlOx | 2.4 | 2.1 | 2.3 | 2.2 | 2.5 | 2.2 | 2.3 |
| | | Mo | 158.0 | 163.0 | 142.0 | 180.0 | 121.0 | 15 [symbol] .0 | 16 [symbol] .0 |

| | | | | | | | |
|---|---|---|---|---|---|---|---|
| Deflect suppressibilty | 251 | 2 [symbol] 0 | 215 | [symbol] | 298 | 311 | 22 [symbol] |

| | | | Example 37 | Example 38 | Example 39 | Example 40 | Example 41 |
|---|---|---|---|---|---|---|---|
| Composition | Chelating | CA1 | | | 1 | [symbol] | |
| | agent | CA2 | | 0.05 | | | 0.1 |
| | | CA3 | | | | | |
| | | CA4 | | | | | |
| | | CA5 | | | | | |
| | | CA6 | | | | | |
| | | CA7 | 0.1 | | | | 0.1 |
| | pH | | 10.50 | 10.50 | 10.50 | 10.50 | 10.50 |
| | Residue removability | | A | A | A | A | A |
| Evaluation | Anticorrosion | Co | 0.5 | 0.7 | 0.7 | 0.3 | 0.6 |
| | properties | W | 5.2 | 3.4 | 5.2 | 5.4 | 3.2 |
| | (Å/min) | TiN | 0.4 | 0.4 | 0.4 | 0.6 | 0.4 |
| | | AlOx | 2.3 | 2.3 | 2.4 | 2.5 | 2.3 |
| | | Mo | [symbol] | 173.0 | 157.0 | 171.0 | 18 [symbol] .0 |

| | | | | | |
|---|---|---|---|---|---|
| Deflect suppressibilty | 256 | 301 | 255 | 211 | 265 |

[symbol]

indicates data missing or illegible when filed

As shown in Table 2, it has been confirmed that the compositions of Examples 31 to 41 have good residue removability similar to that of Example 2. As a result, it has been found that the compositions of Examples 31 to 41 are more excellent in residue removability as compared with the composition of Comparative Example 1.

In addition, it has been confirmed that in a case where the composition contains a chelating agent, the evaluation result of the residue removability is A even in a short-time immersion as compared with the composition of Example 2, and thus the residue removability is more excellent (the comparison among Examples 2 and 31 to 41). Further, it has been confirmed that the evaluation results of the anticorrosion properties and the defect suppressibility were also excellent, which were similar to those of Example 2.

### Examples 42 to 45

[Preparation of Composition]

Compositions of Examples 42 to 45 were prepared according to the following procedure.

It is noted that the chelating agent used was the same as the chelating agent used in the preparation of the compositions of Examples 31 to 41. The notation of each chelating agent is also the same as those described above.

A composition of Example 42 was prepared in the same manner as the composition of Example 11, except that in the prescription of Example 11, the content of deionized water was adjusted, 0.1% by mass of CA1 was added as a chelating agent, and the pH of the composition was adjusted to 10.5 by the content of 2-aminoethanol.

A composition of Example 43 was prepared in the same manner as in Example 42, except that in the prescription of Example 42, the chelating agent was changed to 1.0% by mass of CA1.

A composition of Example 44 was prepared in the same manner as in Example 42, except that in the prescription of Example 42, the chelating agent was changed to 0.1% by mass of CA3.

A composition of Example 45 was prepared in the same manner as in Example 42, except that in the prescription of Example 42, the chelating agent was changed to a mixture of 0.05% by mass of CA2 and 0.05% by mass of CA6.

[Evaluation]

Residue removability was evaluated regarding the compositions of Examples 42 to 45 and the composition of Example 11 for reference by the same method as the evaluation method for the residue removability in the compositions of Examples 31 to 41. It has been confirmed that the compositions of Examples 42 to 45 have a small content of fluorine atoms on the surface of the test piece as compared with the composition of Example 11 and have better residue removability.

In addition, it has been confirmed that as a result of carrying out the evaluation according to the same method as the evaluation method for the compositions of Examples 1 to 30, the evaluation of the anticorrosion properties and the defect suppressibility are excellent, which is similar to the composition of Example 11.

### EXPLANATION OF REFERENCES

1: substrate
2: metal layer
3: etching stop layer
4: interlayer insulating film
5: metal hard mask
6: hole
10: laminate
11: inner wall
11a: cross-sectional wall
11b: bottom wall
12: dry etching residue

What is claimed is:

1. A composition for a semiconductor device, comprising:
alcohol;
an aprotic polar solvent;
an azole compound;
an alkanolamine; and
water.

2. The composition according to claim 1,
wherein a pH is 9 to 11.

3. The composition according to claim 1,
wherein the alcohol includes a monoalcohol.

4. The composition according to claim 1,
wherein the alcohol includes a monoalcohol having a main chain skeleton consisting of an aliphatic hydrocarbon group and an alcoholic hydroxyl group, or a polyhydric alcohol having a main chain skeleton consisting of an aliphatic hydrocarbon group and an alcoholic hydroxyl group.

5. The composition according to claim 1,
wherein the aprotic polar solvent includes at least one selected from the group consisting of dimethyl sulfoxide or sulfolane.

6. The composition according to claim 1,
wherein the aprotic polar solvent includes sulfolane.

7. The composition according to claim 1, further comprising:
a component A selected from the group consisting of sulfolene and dipropyl sulfone.

8. The composition according to claim 7,
wherein a content of the component A is 100 ppt by mass or more and 100 ppm by mass or less with respect to a total mass of the composition.

9. The composition according to claim 7,
wherein a mass ratio of a content of the azole compound to a content of the component A is 1.0×10³ to 1.0×10¹⁰.

10. The composition according to claim 7,
wherein a mass ratio of the content of the aprotic polar solvent to a content of the component A is 1.0×10⁴ to 1.0×10¹⁰.

11. The composition according to claim 1,
wherein the alcohol includes at least one selected from the group consisting of methanol, ethanol, 1-propanol, 2-propanol, 1-butanol, 2-butanol, t-butanol, 1-pentanol, 3-pentanol, and cyclopentanol.

12. The composition according to claim 1,
wherein a content of the alcohol is 50% to 80% by mass with respect to a total mass of the composition.

13. The composition according to claim 1,
wherein a content of the aprotic polar solvent is 1% to 20% by mass with respect to a total mass of the composition.

14. The composition according to claim 1,
wherein the azole compound includes at least one selected from the group consisting of 1,2,4-triazole, 1,2,3-triazole, 1H-tetrazole, 5-aminotetrazole, 1H-benzotriazole, tolyltriazole, 5-methyltriazole, carboxybenzotriazole, and 2,2′-[{(methyl-1H-benzotriazole-1-yl)methyl}imino]bisethanol.

15. The composition according to claim 1,
wherein a content of the azole compound is 0.1% to 5% by mass with respect to a total mass of the composition.

16. The composition according to claim 1,
wherein a content of the water is 10% to 40% by mass with respect to a total mass of the composition.

17. The composition according to claim 1,
wherein the alkanolamine includes at least one selected from the group consisting of diethanolamine, 2-(2-aminoethylamino)ethanol, 2-(2-aminoethoxy)ethanol, triethanolamine, 2-aminoethanol, N,N-dimethylethanolamine, N,N-diethylethanolamine, N-methyldiethanolamine, N-ethyldiethanolamine, and N-methylethanolamine.

18. The composition according to claim 1,
wherein a content of the alkanolamine is 0.3% to 10% by mass with respect to a total mass of the composition.

19. The composition according to claim 1, further comprising:
a chelating agent.

20. The composition according to claim 19,
wherein the chelating agent has a coordinating group selected from the group consisting of a carboxy group, a phosphonate group, a phosphate group, and an amino group.

21. The composition according to claim 19,
wherein the chelating agent includes at least one selected from the group consisting of an amino polycarboxylic acid and a polycarboxylic acid.

22. A substrate washing method comprising:
a washing step of washing a substrate including a metal layer, by using the composition according to claim 1.
